(19) United States
(12) Patent Application Publication
(10) Pub. No.: US 2025/0126774 A1
(43) Pub. Date: Apr. 17, 2025

(54) 3-D DRAM WORDLINE PARTITION AND STAIRCASE CONTACTS

(71) Applicant: Applied Materials, Inc., Santa Clara, CA (US)

(72) Inventors: Chang Seok Kang, Santa Clara, CA (US); Sony Varghese, Manchester, MA (US); Tong Liu, Folsom, CA (US); Fredrick Fishburn, Belmont, CA (US)

(73) Assignee: Applied Materials, Inc., Santa Clara, CA (US)

(21) Appl. No.: 18/403,930

(22) Filed: Jan. 4, 2024

Related U.S. Application Data
(60) Provisional application No. 63/544,071, filed on Oct. 13, 2023.

(51) Int. Cl. H10B 12/00

(52) U.S. Cl. CPC H10B 12/482; H10B 12/02; H10B 12/485; H10B 12/488

(57) ABSTRACT

Memory devices are provided which have stacked DRAM cells, resulting in an increase in DRAM cell bit-density. In a 3D DRAM with stacked unit cell layers of one or more embodiments, it is necessary to reduce the area of a unit cell in order to increase bit density per unit area for a given number of stacked cells. In one or more embodiments, n wordlines (nWL, n is an integer≥2) share a contact pad. The shared nWLs are separated by n bitlines (BLs) to assign every cell independently one WL and one BL.

### CROSS-REFERENCE TO RELATED APPLICATIONS

This application claims priority to U.S. Provisional Application No. 63/544,071, filed Oct. 13, 2023, the entire disclosure of which is hereby incorporated by reference herein.

### TECHNICAL FIELD

Embodiments of the present disclosure pertain to the field of electronic devices and electronic device manufacturing. More particularly, embodiments of the disclosure provide a three-dimensional (3D) dynamic random-access memory cell having a reduced wordline pad area.

### BACKGROUND

Electronic devices, such as personal computers, workstations, computer servers, mainframes, and other computer related equipment such as printers, scanners and hard disk drives use memory devices that provide substantial data storage capability, while incurring low power consumption. There are two major types of random-access memory cells, dynamic and static, which are well-suited for use in electronic devices. Dynamic random-access memories (DRAMs) can be programmed to store a voltage which represents one of two binary values but require periodic reprogramming or “refreshing” to maintain this voltage for more than very short periods of time. Static random-access memories (SRAM) are so named because they do not require periodic refreshing.

DRAM memory circuits are manufactured by replicating millions of identical circuit elements, known as DRAM cells, on a single semiconductor wafer. Each DRAM cell is an addressable location that can store one bit (binary digit) of data. In its most common form, a DRAM cell consists of two circuit components: a field effect transistor (FET) and a capacitor.

The manufacturing of a DRAM cell includes the fabrication of a transistor, a capacitor, and three contacts: one each to the bitline, the wordline, and the reference voltage. DRAM manufacturing is a highly competitive business. There is continuous pressure to decrease the size of individual cells and to increase memory cell density to allow more memory to be squeezed onto a single memory chip, especially for densities greater than 256 Megabits. Limitations on cell size reduction include the passage of both active and passive wordlines through the cell, the size of the cell capacitor, and the compatibility of array devices with nonarray devices.

State-of-the-art horizontal wordline 3D DRAM has one individual wordline staircase running through one column of memory cells. The landing area is normally good for one contact to wordline, or wordline contact (WLCon). For each sub-block in a DRAM, the wordlines and bitlines need to be connected with controlling circuits. Every wordline of each stack should have a contact to connect the wordline with controlling circuits in a sub-array. A number (n) of wordline contacts are necessary in each row of wordlines when nWL memory cells are stacked in 3D DRAM. Thus, the staircase area increases with the number of stacks.

Therefore, there is a need in the art for memory devices and methods of forming memory devices that can accommodate an increased number of bitlines without increasing the chip area.

### SUMMARY

One or more embodiments of the disclosure are directed to a memory device including: a plurality of memory cell units, each memory cell unit including a plurality of memory cells arranged in at least two layers, each layer having memory cells arranged in a grid pattern along with a number of first memory cells spaced in a first direction, a number of second memory cells spaced in a second direction, the layers spaced in a third direction, each memory cell including a capacitor and a transistor; each layer includes a wordline extending from the grid pattern along the first direction, each layer wordline in electrical connection with each memory cell in the layer, the wordlines forming a staircase pattern with a surface accessible along the third direction; a plurality of vertical bitlines for each of the first memory cells, the vertical bitlines located between each of the memory cell units; and a plurality of horizontal bitlines above the memory cell units and extending along the second direction, each of the horizontal bitlines in electrical connection with one of the vertical bitlines adjacent the memory cell unit.

Additional embodiments of the disclosure are directed to methods of forming a memory device, the method including: forming a plurality of memory cell units, each unit including a plurality of memory cells arranged in at least two layers, each layer having a grid pattern, each layer having a wordline extending from the plurality of memory cells in a first direction, each memory cell unit having a vertical bitline extending along a third direction and located adjacent the memory cell unit along a second direction, and horizontal bitlines over the memory cell units, the horizontal bitlines in electrical connection with one vertical bitline on a side of the memory cell unit.

Further embodiments of the disclosure are directed to methods of forming a memory device, the method including: selectively recessing SiGe layers of a plurality of layer stacks through wordline openings formed adjacent a memory region, the layer stacks including alternating layers of SiGe and silicon, the silicon layers alternating between a thin layer and a thick layer, the plurality of layer stacks spaced apart in a first direction with each layer extending along a second direction and the layers stacked in a third direction, a height of the layer stacks decreasing along the first direction with the tallest stacks closest to the memory region; recessing the silicon layers to remove the thin layers and reduce a thickness of the thick layers to leave a layer stack with spaced silicon layers; forming a dielectric layer between the spaced silicon layers; removing the spaced silicon layers from the layer stack to leave spaced dielectric layers; and forming wordlines by depositing a metal layer between the spaced dielectric layers to form a layer stack having alternating dielectric layers and wordlines including metal layers, the wordlines extending outward from the memory region in a staircase pattern.

### BRIEF DESCRIPTION OF THE DRAWING

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1A shows a portion of a memory device in which there are half the number of wordline pads and double the number of bitlines of a standard memory array.

FIG. 1B illustrates an expanded view of a portion of the memory device of FIG. 1A showing the bitlines and wordline connections for individual memory cells.

FIG. 1C shows an electronic schematic of the memory device connections for the embodiment illustrated in FIG. 1A.

FIG. 2A shows an embodiment of a memory device in which the number of wordline pads is reduced by ⅓ while the number of bitlines is tripled.

FIG. 2B shows an expanded view of a portion of the memory device of FIG. 2A showing the bitlines and wordline connections for the individual memory cells.

FIG. 2C shows an electronic schematic of the memory device connections for the embodiment illustrated in FIG. 2A.

FIG. 3A illustrates a layer stack on the surface of a substrate.

The layer stack, as shown in the expanded view of region 3B in FIG. 3B, comprises alternating layers of a first material (e.g., silicon (Si)) and a second material (e.g., silicon germanium (SiGe)).

FIG. 4 illustrates the electronic device of FIG. 3A after recessing a first tier on one side of a memory region.

A staircase is formed by alternating the etching/trimming of the layer stack on opposite sides of the memory region to arrive at a layout similar to that illustrated in FIGS. 5A and 5B.

FIG. 6 illustrates the electronic device after deposition of a dielectric material on the exposed surfaces of the staircase.

FIG. 7 illustrates the electronic device of FIG. 6 after isolating the memory region by etching to leave isolation trenches adjacent either side of the memory region.

FIG. 8A illustrates the electronic device of FIG. 7 after deposition of additional dielectric material to fill the isolation trenches and end trenches.

FIG. 8B shows an expanded view of region 8B shown in FIG. 8A.

FIG. 9A illustrates the electronic device of FIG. 8A after a deep trench isolation process to leave wordline openings.

FIG. 9B shows an expanded view of region 9B of FIG. 9A.

FIG. 10A illustrates the electronic device of FIG. 9A after deposition of an etch stop layer on the top surface of the memory region and the dielectric material.

FIG. 10B shows an expanded view of region 10B of FIG. 10A.

FIG. 11 shows region 10B of FIG. 10B after selectively recessing the second material layers from a plurality of layer stacks through the wordline openings to form gaps.

FIG. 12 shows the region of FIG. 11 after recessing the first material layers through the wordline openings.

FIG. 13 shows the region of FIG. 12 after formation of a dielectric layer between the spaced first material layers.

FIG. 14 shows the region of FIG. 13 after removing the dielectric layer from the sidewalls of the layer stacks.

FIG. 15 shows the region of FIG. 14 after removing the spaced first material layers from layer stacks between the dielectric layer, leaving spaced dielectric layers.

FIG. 16 shows the region of FIG. 15 after depositing a metal layer between the spaced dielectric layers.

FIG. 17 shows the region of FIG. 16 after a sidewall metal recess process.

FIG. 18 shows the region of FIG. 17 after deposition of a gap fill material.

FIG. 19 shows the region of FIG. 18 after a bitline etch process to form vertical bitline openings.

FIG. 20 shows the region of FIG. 19 after deposition of the vertical bitline in the vertical bitline openings.

FIG. 21A shows the electronic device of FIG. 20 after etching bitline contact openings.

FIG. 21B shows an expanded view of region 21B showing the bitline contact opening.

FIG. 21C shows a cross-sectional view through the bitline contact openings in region 21C along line 21-21′.

FIG. 22 shows the electronic device of FIG. 21A after depositing a bitline metal contact layer on the surface of the substrate.

FIG. 23 shows the electronic device of FIG. 22 after formation of a bitline strap hardmask.

FIG. 25 shows the electronic device of FIG. 24 after a bitline strap capping deposition process.

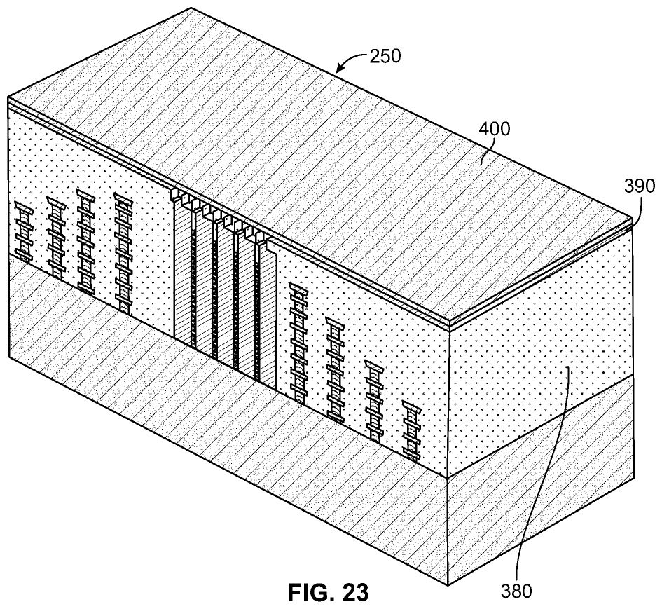

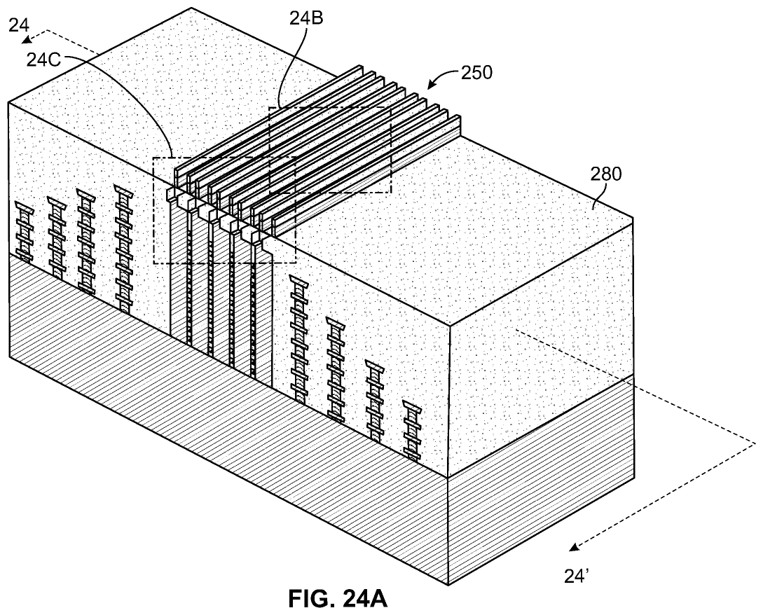

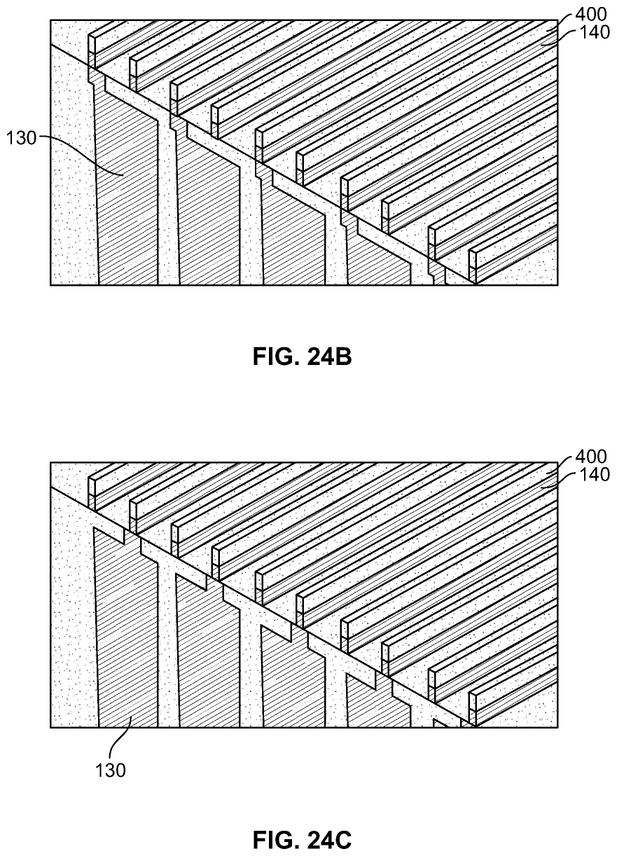

FIG. 24A shows the electronic device of FIG. 23 after formation of the bitline strap, also referred to as a horizontal bitline. FIG. 24B shows an expanded view of region 24B of FIG. 24A to show the offset connections of the bitline straps with the vertical bitlines.

FIG. 24C shows an expanded view of region 24C of FIG. 24A taken along line 24-24′.

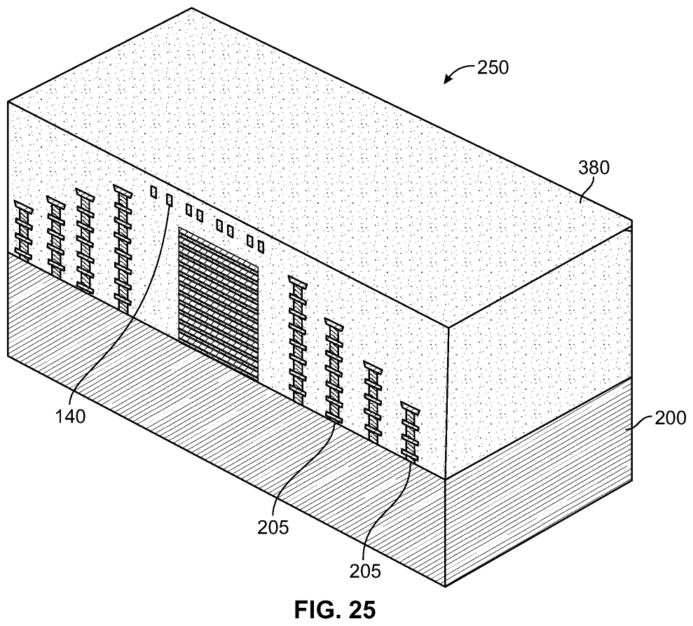

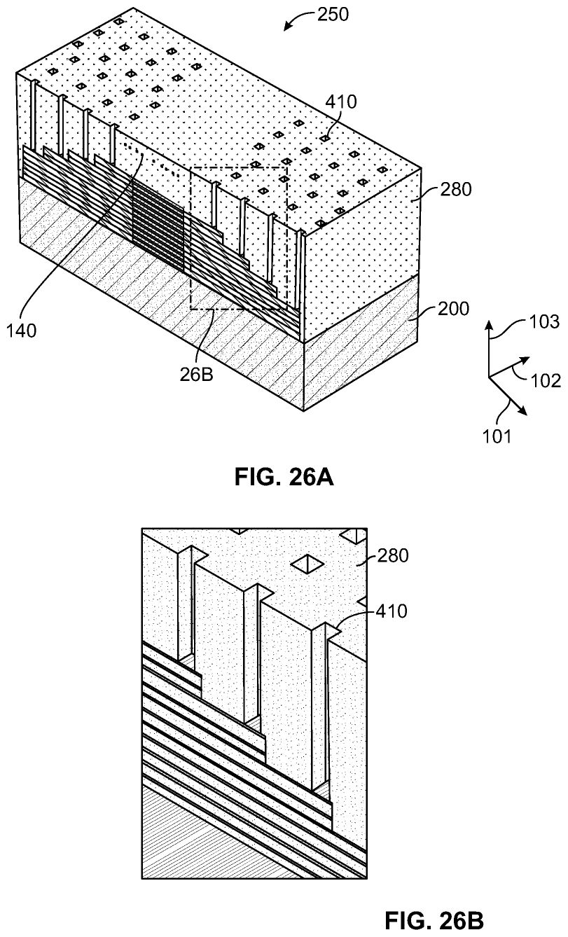

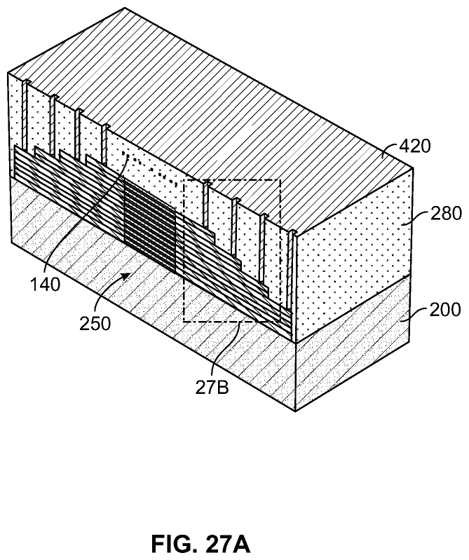

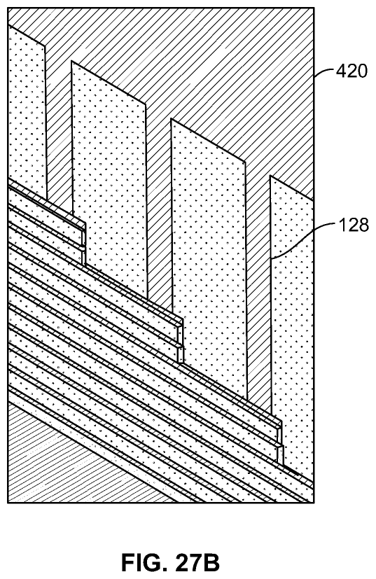

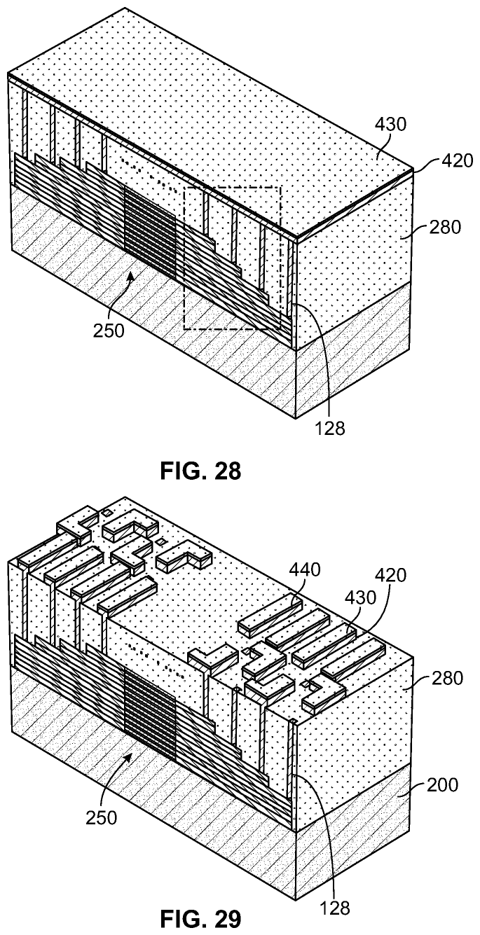

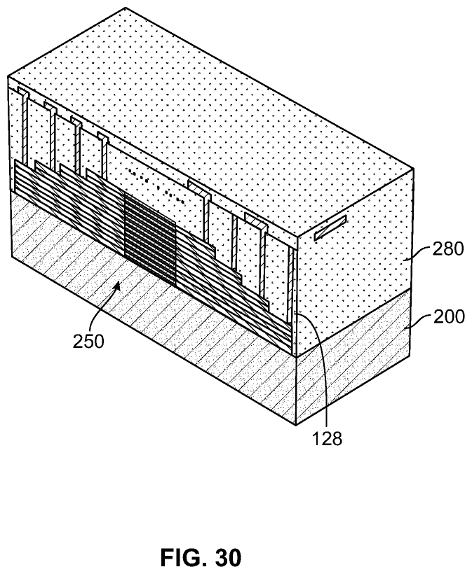

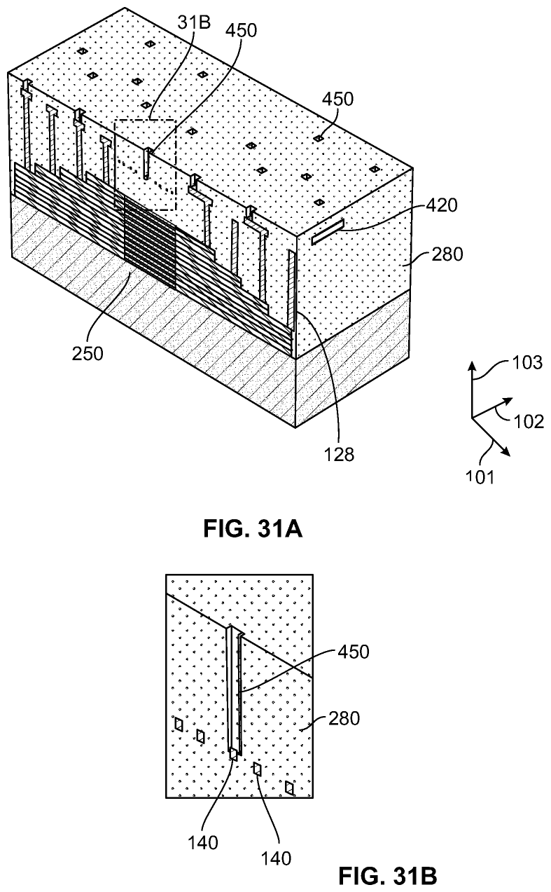

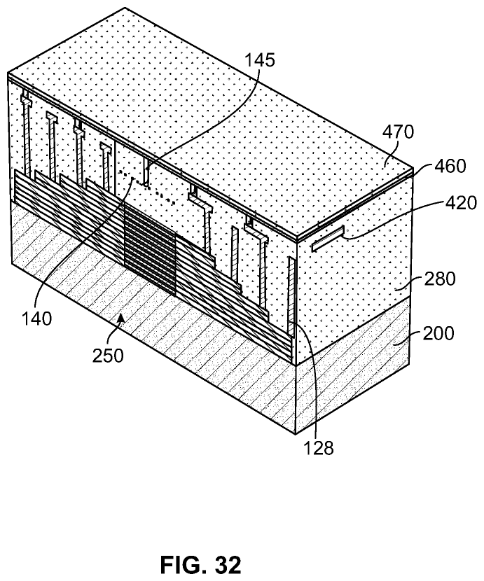

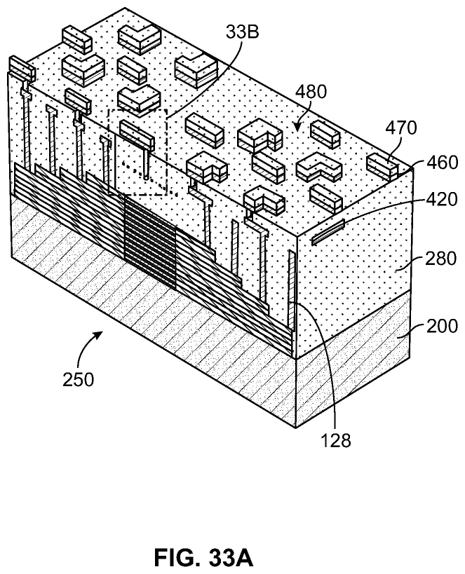

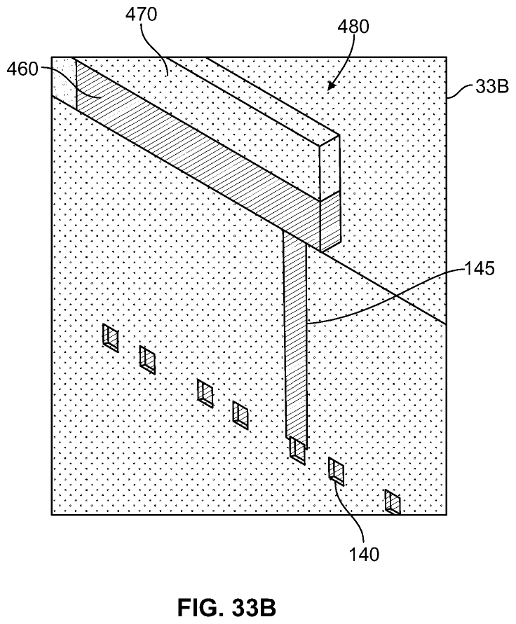

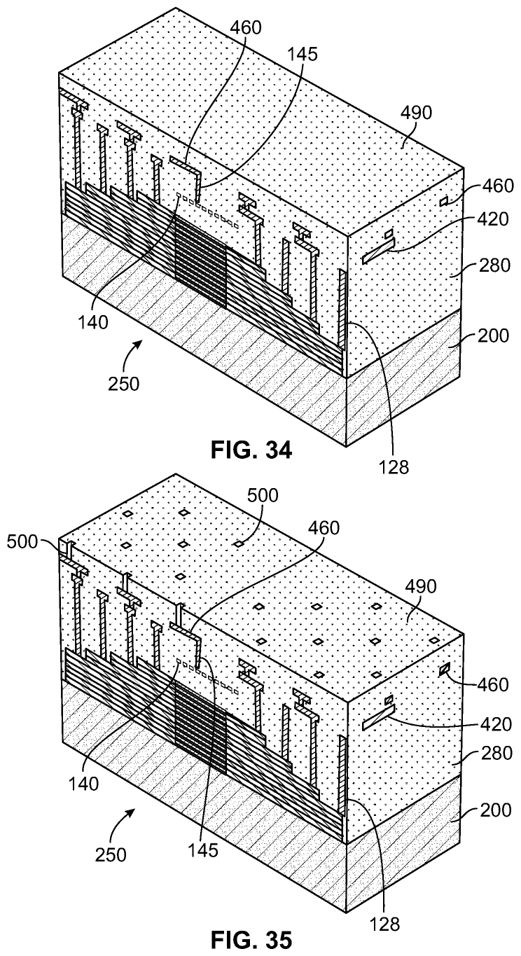

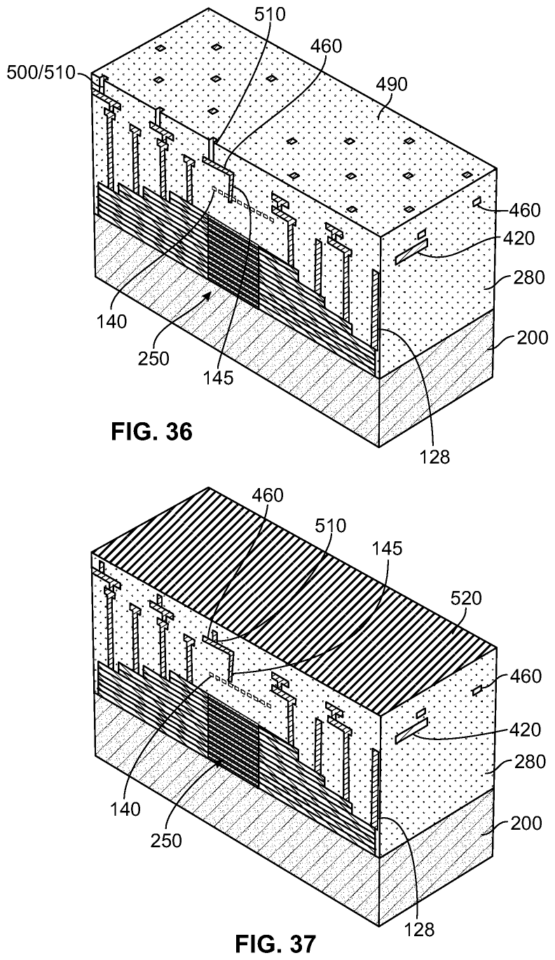

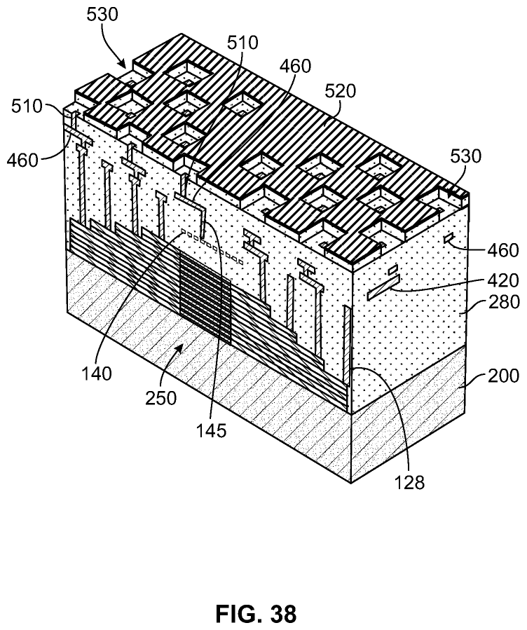

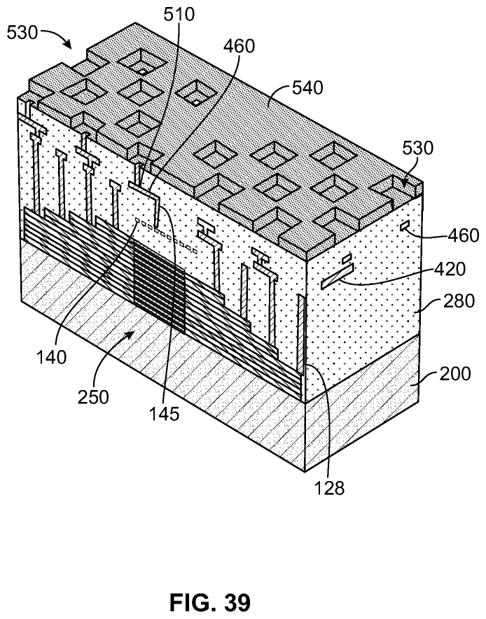

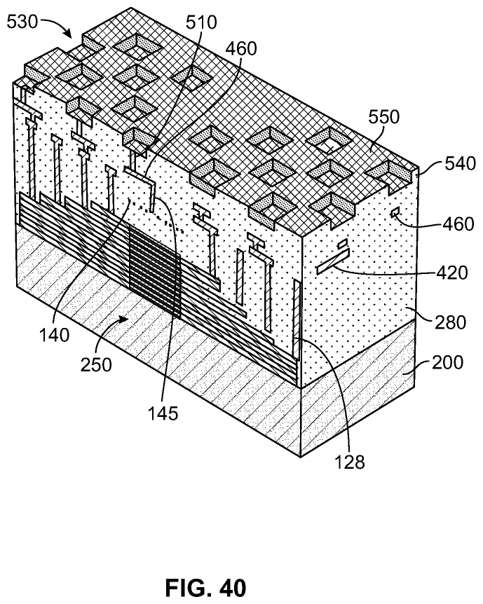

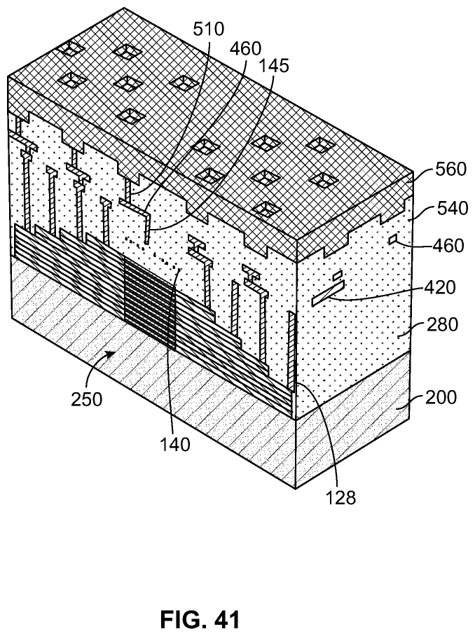

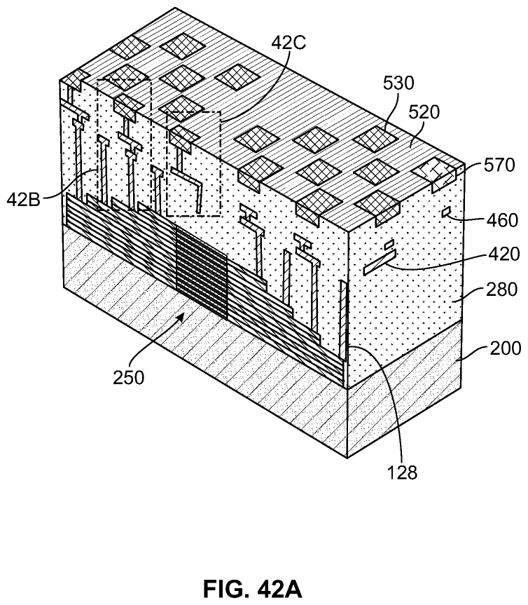

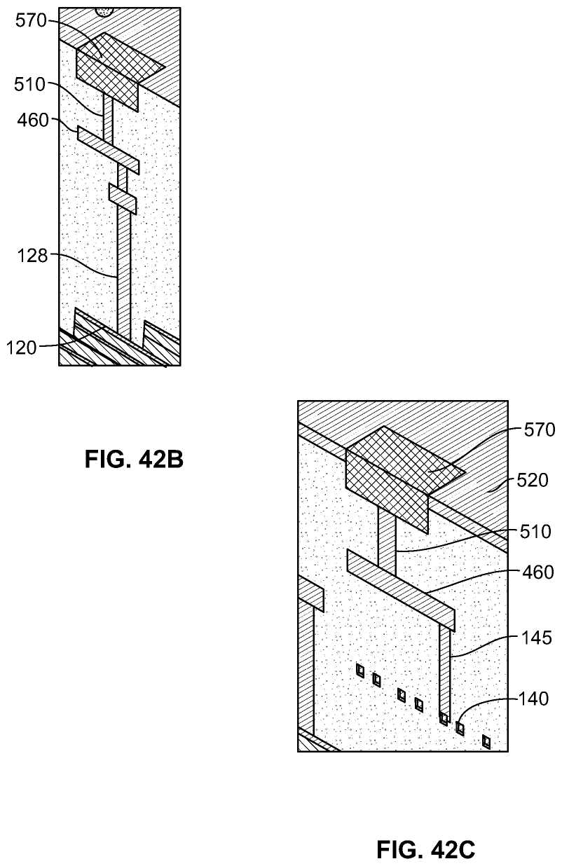

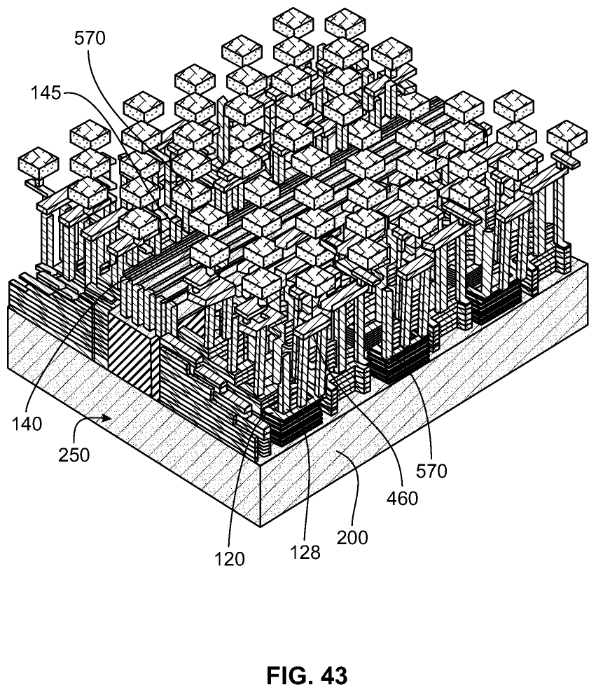

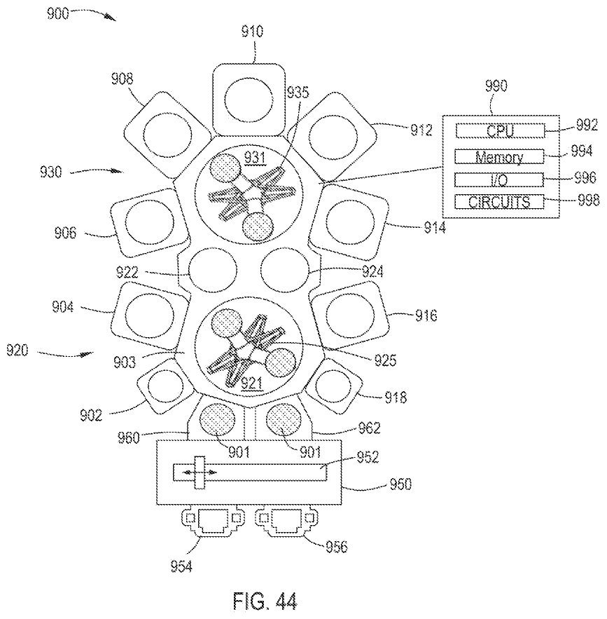

FIG. 25 shows the electronic device of FIG. 24 after a bitline strap capping deposition process.

FIG. 26A shows the electronic device of FIG. 25 after formation of wordline contact openings.

FIG. 26B is an expanded view of region 26B of FIG. 26A.

FIG. 27A shows the electronic device of FIG. 26A after formation of a wordline contact metal layer on the substrate and in the wordline contact openings.

FIG. 27B is an expanded view of region 27B of FIG. 27A.

FIG. 28 shows the electronic device of FIG. 27A after formation of a wordline contact strap hardmask on the wordline contact metal layer.

FIG. 29 shows the electronic device of FIG. 28 after etching the wordline contact straps through the wordline contact strap hardmask and wordline contact metal layer.

FIG. 30 shows the electronic device of FIG. 29 after a gap fill process to cover the wordline contact straps.

FIG. 31A shows the electronic device of FIG. 30 after etching vertical vias along the third direction to contact the horizontal bitlines.

FIG. 31B shows an expanded view of region 31B of FIG. 31A.

FIG. 32 shows the electronic device of FIG. 31A after deposition of a via metal and hardmask.

FIG. 33A shows the electronic device of FIG. 32 after redistribution layer etching to form the redistribution layer.

FIG. 33B shows an expanded view of region 33B of FIG. 33A showing the redistribution layer with via metal contacting the bitline contact extending in the third direction and contacting the horizontal bitlines.

FIG. 34 shows the electronic device of FIG. 34 after deposition of an interlayer dielectric on the redistribution layer.

FIG. 35 shows the electronic device of FIG. 34 after etching vias through the interlayer dielectric to the via metal.

FIG. 36 shows the electronic device of FIG. 35 after deposition of via metal in the vias.

FIG. 37 shows the electronic device of FIG. 36 after deposition of an interlayer dielectric on the via metal.

FIG. 38 shows the electronic device of FIG. 37 after deposition a bonding pad etch to create bonding pad openings.

FIG. 39 shows the electronic device of FIG. 38 after deposition of a barrier layer on the interlayer dielectric and in the bonding pad openings.

FIG. 40 shows the electronic device of FIG. 39 after deposition of a seed layer on the barrier layer.

FIG. 41 shows the electronic device of FIG. 40 after a metal plating process to form a metal layer.

FIG. 42A shows the electronic device of FIG. 41 after formation of the bonding pads.

FIG. 42B shows region 42B of FIG. 42A showing the connection along the third direction between the bonding pad and the wordlines.

FIG. 42C shows region 42C of FIG. 42A showing the connection along the third direction between the bonding pad and the horizontal bitlines.

FIG. 43 shows a portion of an electronic device formed by one or more of the embodiments described showing the conductive pathways to the staircase structure and the memory region.

FIG. 44 shows a schematic representation of a processing tool for formation of the electronic devices described according to one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the terms “precursor”, “reactant”, “reactive gas” and the like are used interchangeably to refer to any gaseous species that can react with the substrate surface.

In the following description, numerous specific details, such as specific materials, chemistry, dimensions of the elements, etc. are set forth in order to provide thorough understanding of one or more of the embodiments of the present disclosure. It will be apparent, however, to one of ordinary skill in the art that the one or more embodiments of the present disclosure may be practiced without these specific details. In other instances, semiconductor fabrication processes, techniques, materials, equipment, etc., have not been described in great detail to avoid unnecessarily obscuring this description. Those of ordinary skill in the art, with the included description, will be able to implement appropriate functionality without undue experimentation.

While certain exemplary embodiments of the disclosure are described and shown in the accompanying drawings, it is to be understood that such embodiments are merely illustrative and not restrictive of the current disclosure, and that this disclosure is not restricted to the specific constructions and arrangements shown and described because modifications may occur to those ordinarily skilled in the art.

As used herein, the term “dynamic random access memory” or “DRAM” refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor. The DRAM device is formed of an array of DRAM cells.

Traditionally, DRAM cells have recessed high work-function metal structures in buried wordline structure. In a DRAM device, a bitline is formed in a metal level situated above the substrate, while the wordline is formed at the polysilicon gate level at the surface of the substrate. In the buried wordline (bWL), a wordline is buried below the surface of a semiconductor substrate using a metal as a gate electrode.

In one or more embodiments, memory devices are provided which have stacked DRAM cells, resulting in an increase in DRAM cell bit-density. In a 3D DRAM with stacked unit cell layers of one or more embodiments, it is necessary to reduce the area of a unit cell in order to increase bit density per unit area for a given number of stacked cells. In one or more embodiments, n wordlines (nWL, n is an integer≥2) share a contact pad. The shared nWLs are separated by n bitlines (BLs) to assign every cell independently one WL and one BL.

Some embodiments advantageously provide memory devices and methods of forming memory devices where an increased number of bitlines are shared by wordline contacts without increasing the chip area. Some embodiments advantageously address the tight pitch and critical dimension (CD) requirements for contacts and hybrid bonding to pads to the horizontal wordline staircase of 3D DRAM devices. In some embodiments, the array-to-peripheral hybrid bonding has increased spatial flexibility relative to a conventional memory device. In some embodiments, a wordline staircase of columns of cells share the same plate at different levels of the columns. In some embodiments, the common wordline staircase provides more room for the pitch and critical dimension of the wordline contacts and hybrid bonding pads.

In some embodiments, the contact landing area of horizontal wordline staircase increases by grouping the wordline staircases of different columns of the memory cells. The larger landing area of some embodiments relaxes the pitch of the contacts to wordlines. In some embodiments, multiple contacts can drop on the grouped common wordline staircase and contact reliability is improved. In one or more embodiments, the scale of the wordline decoder can be decreased as two (or more) wordline staircases are grouped. In some embodiments, the number of hybrid bonding pads is reduced due to the grouped wordline staircases.

Briefly, with further details provided herein, the 3D DRAM starts from Si/SiGe superlattice stack deposition. Outside the array region of memory cells, the Si/SiGe wordline staircase is formed by repeating photoresist trim and Si/SiGe etch steps. The boundary of array and staircase regions is patterned for isolation. A deep trench isolation etch is used to pattern the connection loops between two (or more) wordline staircases. The SiGe in the staircase region is selectively removed and replaced with an atomic layer deposition (ALD) oxide. The oxide deposited on sidewall is recessed to expose Si in the staircase. The Si in staircase is selectively removed and replaced with ALD wordline metal. The metal deposited on the sidewall is cleaned to eliminate short-circuits. After bitlines are formed, bitline straps and contacts to bitlines are patterned. Wordline contact straps are patterned together with contacts to the wordlines. Vias, redistribution layers (RDL), and/or bonding pads can be formed subsequently for array-to-peripheral hybrid bonding.

A standard DRAM memory array has one wordline and one bitline for every memory cell. Embodiments of the disclosure have unequal wordline and bitlines depending on the number of the memory cells in each memory cell unit.

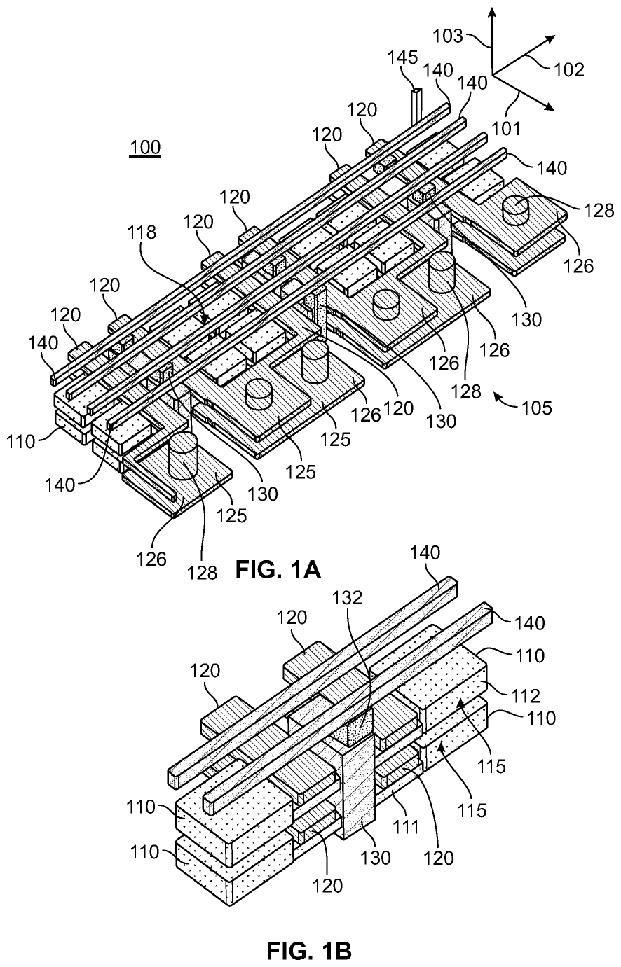

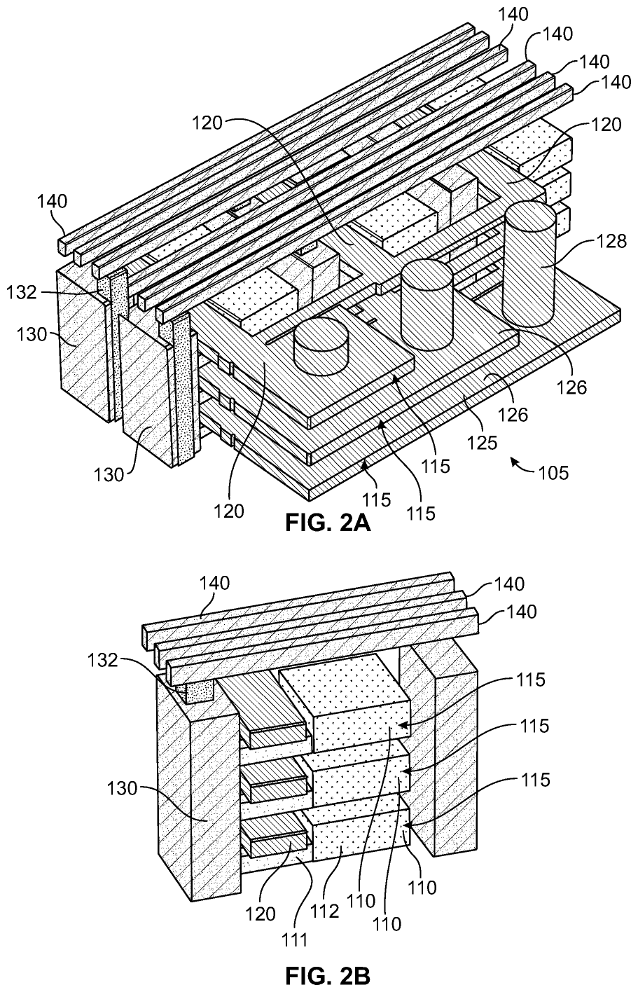

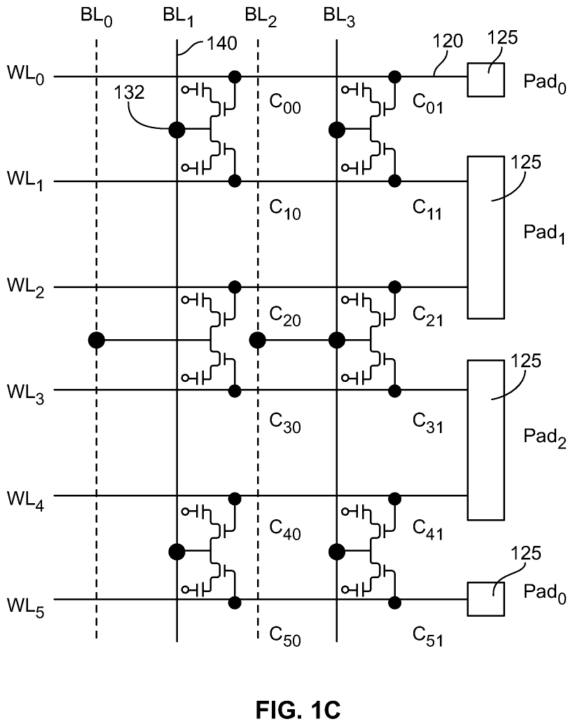

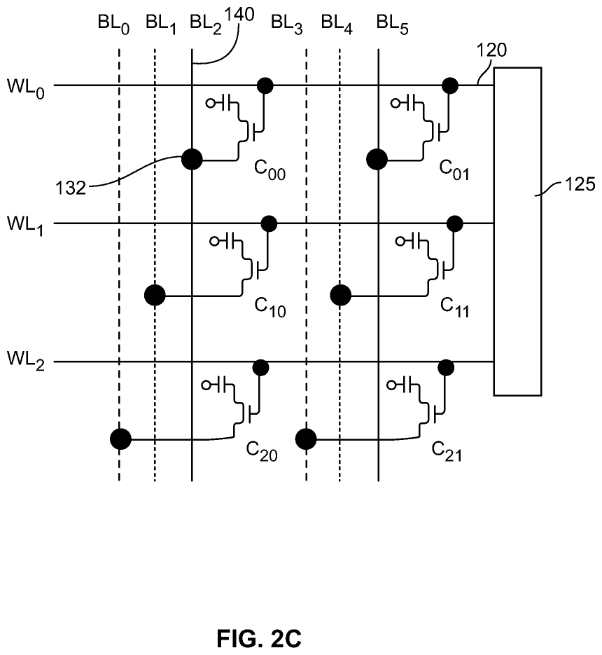

Referring to FIGS. 1A through 2C, some embodiments of the disclosure are directed to memory devices 100. FIG. 1A shows a portion of a memory device 100 in which there are half the number of wordline pads and double the number of bitlines of a standard memory array. FIG. 1B illustrates an expanded view of a portion of the memory device 100 of FIG. 1A showing the bitlines and wordline connections for individual memory cells. FIG. 1C shows an electronic schematic of the memory device connections for the embodiment illustrated in FIG. 1A.

FIG. 2A shows an embodiment of a memory device 100 in which the number of wordline pads is reduced by ⅓ while the number of bitlines is tripled. FIG. 2B shows an expanded view of a portion of the memory device 100 of FIG. 2A showing the bitlines and wordline connections for the individual memory cells. FIG. 2C shows an electronic schematic of the memory device connections for the embodiment illustrated in FIG. 2A.

In general, k wordlines are shared by one wordline pad while the bitline contacts of the wordlines shared by the one wordline pad are separated by k bitlines. For example, FIGS. 1A through 1C show an embodiment in which k=2; where two wordlines are connected by a single wordline pad while the bitline contacts for the wordlines shared by a single wordline pad are separated by two bitlines.

Some embodiments of the disclosure are directed to memory devices 100 comprising a plurality of memory cell units 105. Each memory cell unit 105 comprises a plurality of memory cells 110 arranged in at least two layers 115. For example, the embodiment illustrated in FIG. 1A has two layers 115 while the embodiment illustrated in FIG. 2A has three layers 115. For descriptive purposes, a coordinate axis is illustrated on FIG. 1A showing a first direction 101 (also referred to as an x-axis direction), a second direction 102 (also referred to as a y-axis direction) and a third direction 103 (also referred to as a z-axis direction). The skilled artisan will recognize that the axes illustrated are for ease of description and do not imply or limit the disclosure to any physical orientation in space. For example, the layers 115 illustrated are within the plane formed by the first direction 101 and the second direction 102 with a thickness in the third direction 103. The layers 115 are stacked along the third direction 103 so that one layer 115 is “on top of” another layer 115. The axes illustrated show the first direction 101, second direction 102 and third direction 103 approximately orthogonal to each other. However, the skilled artisan will recognize that this is merely one possible arrangement of the axes and that the individual axes can lie at angles other than 90° relative to each other.

Each layer 115 has memory cells 110 arranged in a grid pattern 118 so that there are a number of first memory cells spaced in the first direction 101, a number of second memory cell spaced in the second direction 102, and the layers 115 spaced in the third direction 103. In a grid or matrix or memory cells, each memory cell 110 is a first memory cell spaced from another memory cell 110 in the first direction 101, and a second memory cell spaced from another memory cell 110 in the second direction 102.

Each memory cell 110 is a stack of layers that comprise a transistor 111 and a capacitor 112. The skilled artisan will be familiar with the layout and formation of capacitors 112 and transistors 111 in a DRAM device. For example, U.S. Pat. No. 11,594,537 describes a process for making a memory device which includes the formation of the memory cells.

Each layer 115 of memory cells 110 includes a wordline 120 extending from the grid pattern 118 along the first direction 101. The wordline 120 includes a wordline pad 125 and is in electrical connection with each memory cell 110 in the layer 115. For example, the embodiment illustrated in FIG. 1A each layer 115 has a grid pattern 118 with two memory cells 110 spaced along the first direction 101 and two memory cells spaced along the second direction 102, with one wordline 120 in electrical connection with each cell 110 in the layer 115 and the wordline pad 125 of the layer 115.

The wordlines 120 (which include the wordline pad 125) form a staircase pattern with a surface 126 accessible along the third direction 103. In some embodiments, the layers 115 have a wordline 120 (including the wordline pad 125) that extend from the memory cell 110 in the first direction 101. The surfaces 126 of the wordline pad 125 for each layer 115 in a memory cell unit 105 are sized to stagger along the second direction 102 so that the surface 126 is accessible for a contact 128 to be formed. A single contact 128 can provide electrical connection to all of the memory cells 110 of a layer 115 of the memory cell unit 105.

The memory device 100 includes a plurality or vertical bitlines 130. Each of the vertical bitlines 130 are located between the memory cell units 105. As used in this manner, the term “vertical” means that the bitline extends along the third direction 103. The term “vertical” does not imply, and should not be limited to, any particular direction relative to gravity. Rather, a vertical bitline 130 connects the layers 115 of the memory cell unit 105 along the third direction 103.

The memory device 100 includes a plurality of horizontal bitlines 140 above the memory cell units 105. The horizontal bitlines 140 extend along the second direction 102. Each of the horizontal bitlines 140 is in electrical connection with one of the vertical bitlines 130 adjacent the memory cell unit 105. The horizontal bitlines 140 can connect to the vertical bitlines 130 through a bitline connector 132. Each horizontal bitline 140 connects to a vertical bitline 130 through a bitline connector 132 on one side of the layer 115 of the memory cell unit 105 to allow for the individual addressing of each memory cell 110 within the memory cell unit 105.

In some embodiments, each memory cell unit 105 of the memory device 100 has twice the number of horizontal bitlines 140 than wordlines 120 (which includes the wordline pad 125). In some embodiments, each memory cell unit 105 of the memory device 100 has at least twice the number of horizontal bitlines 140 than wordlines 120 (which includes the wordline pad 125). As used in this manner, the wordlines 120 for any given layer 115 are electrically indistinguishable from each other and the wordline pad 125 that connects directly to the wordlines 120 of the layer 115 and are referred to as a single wordline unless otherwise specified. In some embodiments, each memory cell unit 105 has one wordline 120 (including wordline pad 125) for every layer 115 in the memory cell unit 105. In some embodiments, each memory cell unit 105 has one horizontal bitline 140 for every memory cell 110 in a layer 115 of memory cells 110. For example, in the 2×2×2 grid layout illustrated in FIG. 1A, each layer 115 has four memory cells 110, resulting in two wordlines 120 (including wordline pads 125)—one for each layer 115—and four horizontal bitlines 140. In the 3×2×3 grid layout illustrated in FIG. 2A, each layer 115 has six memory cells 110, resulting in three wordlines 120 (including wordline pad 125)—one for each layer 115—and six horizontal bitlines 140.

In some embodiments, the memory device 100 further comprises a wordline contact 128 extending along the third direction 103 from the surface 126 of the wordline pad 125 that is accessible along the third direction 103. In some embodiments, a wordline contact 128 is in electrical communication with a wordline pad 125 and the associated wordlines 120 for each layer 115 of the memory cell unit 105. In the embodiment in FIG. 2A, each layer 115 of each memory cell unit 105 has one wordline contact 128 in electrical communication with the wordline pad 125 and associated wordlines 120.

To address the individual memory cells 110 through the horizontal bitlines 140 and vertical bitlines 130, a bitline contact 145 extends from the horizontal bitlines 140 in the third direction 103 from each of the horizontal bitlines 140. For clarity, only one bitline contact 145 is illustrated in FIG. 1A.

In some embodiments, as will be described further below with respect to the method of forming the memory device 100, each of the memory cell units 105 independently comprises a stack of alternating insulator and metal layers. The insulator layers of some embodiments comprises an oxide. The oxide layer of some embodiments comprises silicon oxide. The metal layers of some embodiments comprises one or more of titanium nitride (TiN), tungsten (W), or molybdenum (Mo).

Additional embodiments of the disclosure are directed to methods for forming a memory device 100. The methods comprise forming a plurality of memory cell units 105 arranged in at least two layers 115. Each layer 115 has a grid pattern arrangement of memory cells 110. Each layer 115 has a wordline 120 extending from the plurality of memory cells 110 in a first direction 101. Each memory cell unit has a vertical bitline 130 extending along a third direction 103 and located adjacent the memory cell unit 105 along a second direction 102. Horizontal bitlines 140 are formed over (i.e., spaced in the third direction 103) the memory cell units 105. The horizontal bitlines 140 are in electrical connection with one vertical bitline 130 on a side of the memory cell unit 105.

In some embodiments, each of the memory cells 110 in a layer 115 are connected to the same wordline 120 (which includes the associate wordline pad 125). In one or more embodiments, the method comprises forming the wordlines 120 (including the wordline pad 125) in a staircase pattern. The staircase pattern leaves a surface 126 of the wordline pad 125 accessible along the third direction 103. Some embodiments further comprise forming a wordline contact 128 extending in the third direction 103 from the surface 126 of the wordline pad 125 accessible along the third direction 103. Some embodiments of the method further comprise forming bitline contacts 145 extending in the third direction 103 from a surface of the horizontal bitlines 140.

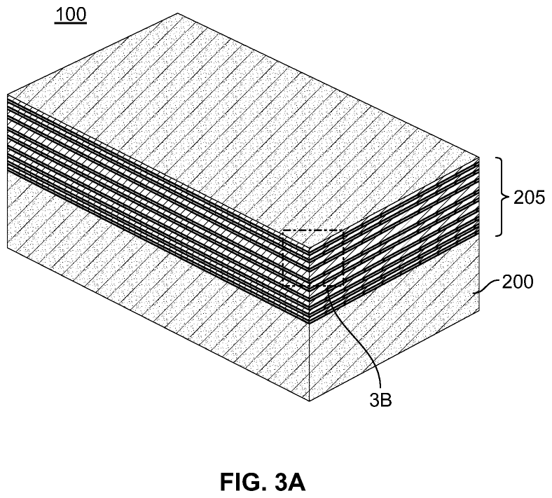

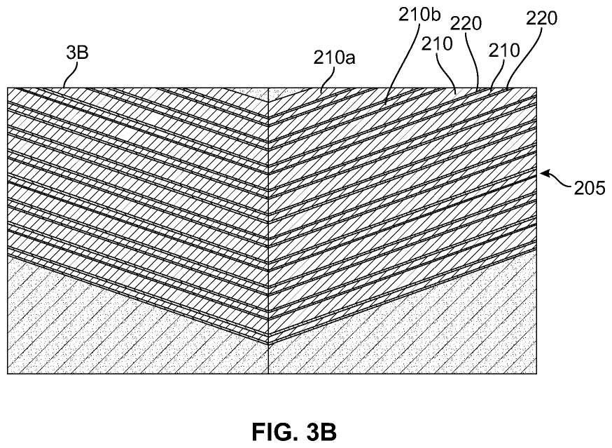

Referring to FIG. 3A through FIG. 43, one or more embodiments of the disclosure are directed to methods of forming a memory device 100. The skilled artisan will recognize that the method can begin at any of the individual stages described herein and can end at any of the individual stages described herein.

FIG. 3A illustrates a layer stack 205 on the surface of a substrate 200. The substrate 200 can be any suitable substrate surface as will be understood by the skilled artisan. The layer stack 205, as shown in the expanded view of region 3B in FIG. 3B, comprises alternating layers of a first material 210 (e.g., silicon (Si)) and a second material 220 (e.g., silicon germanium (SiGe)). In some embodiments, the layers of first material 210 alternate between a thin layer 210a and a thick layer 210b. The number of layers illustrated in the layer stack 205 is merely representative of one possible configuration and should not be taken as limiting the scope of the disclosure.

The substrate 200 can be any suitable material known to the skilled artisan. As used in this specification and the appended claims, the term “substrate” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The layer stack 205 may have any number of alternating first material layers 210 and second material layers 220. In some embodiments, the layer stack 205 comprises alternating first material layers 210, second material layers 220 and sacrificial layers (not shown). The sacrificial layers of some embodiments comprises a material that is etch selective relative to the first material 210 and the second material 220. In some embodiments, the layer stack 205 comprises greater than 50 pairs of alternating first material layers 210 and second material layers 220.

In some embodiments, the first material layers 210, second material layers 220, and sacrificial layers (if included) are made of materials that are etch selective relative to each other. In some embodiments, the first material layers 210 comprises silicon and the second material layers comprises silicon germanium. In some embodiments, the layer stack 205 comprises alternating layers of oxides and polysilicon, nitrides and polysilicon, or oxides and nitrides.

The first material layers 210 and second material layers 220 and sacrificial layers (if present) can be deposited by any suitable technique known to the skilled artisan. For example, the first material layers 210 and second material layers 220 of some embodiments, are deposited by one or more of atomic layer deposition (ALD) chemical vapor deposition (CVD), physical vapor deposition (PVD) or epitaxy.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A, e.g., aluminum precursor) is pulsed into the reaction zone followed by a first time delay. Next, a second precursor or compound B (e.g., oxidant) is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness. In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

As used herein, “chemical vapor deposition” refers to a process in which a substrate surface is exposed to precursors and/or co-reagents simultaneous or substantially simultaneously. As used herein, “substantially simultaneously” refers to either co-flow or where there is overlap for a majority of exposures of the precursors.

Plasma enhanced chemical vapor deposition (PECVD) is widely used to deposit thin films due to cost efficiency and film property versatility. In a PECVD process, for example, a hydrocarbon source, such as a gas-phase hydrocarbon or a vapor of a liquid-phase hydrocarbon that have been entrained in a carrier gas, is introduced into a PECVD chamber. A plasma-initiated gas, typically helium, is also introduced into the chamber. Plasma is then initiated in the chamber to create excited CH-radicals. The excited CH-radicals are chemically bound to the surface of a substrate positioned in the chamber, forming the desired film thereon. Embodiments described herein in reference to a PECVD process can be carried out using any suitable thin film deposition system. Any apparatus description described herein is illustrative and should not be construed or interpreted as limiting the scope of the embodiments described herein.

The individual alternating layers may be formed to any suitable thickness. In some embodiments, the thickness of each second layer is approximately equal. In one or more embodiments, alternating first material layers 210 are about two to five times thicker than the intervening first material layers 210.

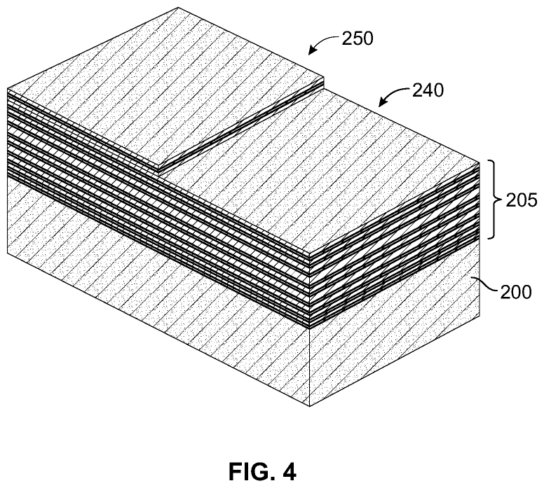

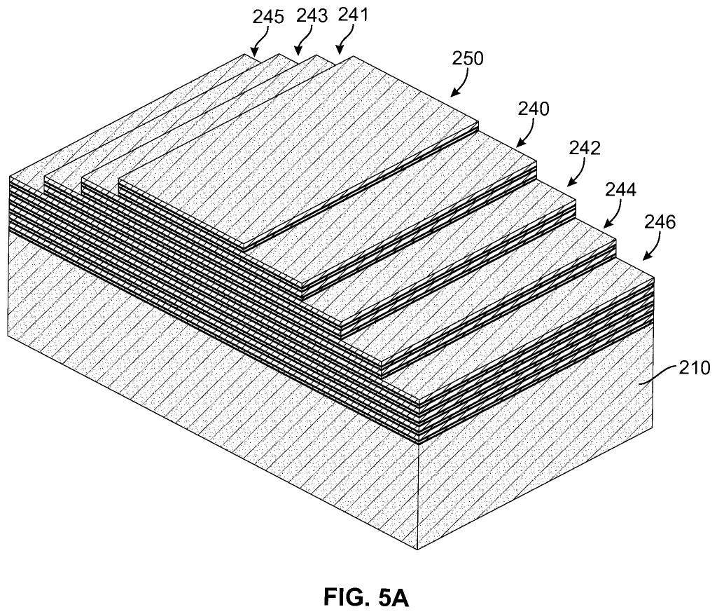

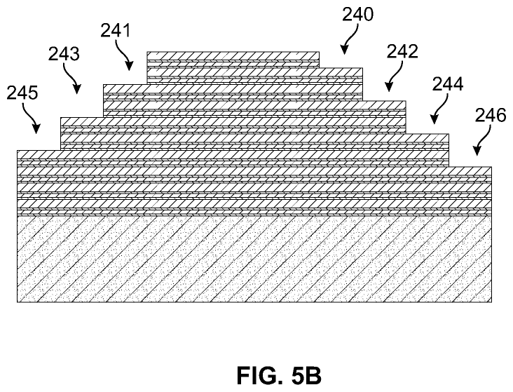

FIG. 4 illustrates the electronic device of FIG. 3A after recessing a first tier 240 on one side of a memory region 250. The memory region 250 is within the layer stack 205 and contains the components of the memory (e.g., capacitor and transistors). The particular components of the memory region 250 are omitted from the drawings for descriptive purposes. However, the skilled artisan will be familiar with the formation and arrangement of these components to arrive at a layout as described, for example, with respect to FIGS. 1A through 2C.

The first tier 240 can be recessed by any suitable technique known to the skilled artisan. For example, a portion of the electronic device can be masked and the layers etched from the layer stack 205 to form the first tier 240. A staircase is formed by alternating the etching/trimming of the layer stack 205 on opposite sides of the memory region 250 to arrive at a layout similar to that illustrated in FIGS. 5A and 5B. The staircase shown has a first tier 240, third tier 242, fifth tier 244 and seventh tier 246 on one side of the memory region 250, with a second tier 241, fourth tier 243 and sixth tier 245 on the opposite side of the memory region 250. The number of tiers illustrated in the drawings is merely representative of one possible configuration and is used for descriptive purposes only. The number of tiers on either side of the memory region 250 of some embodiments are equal.

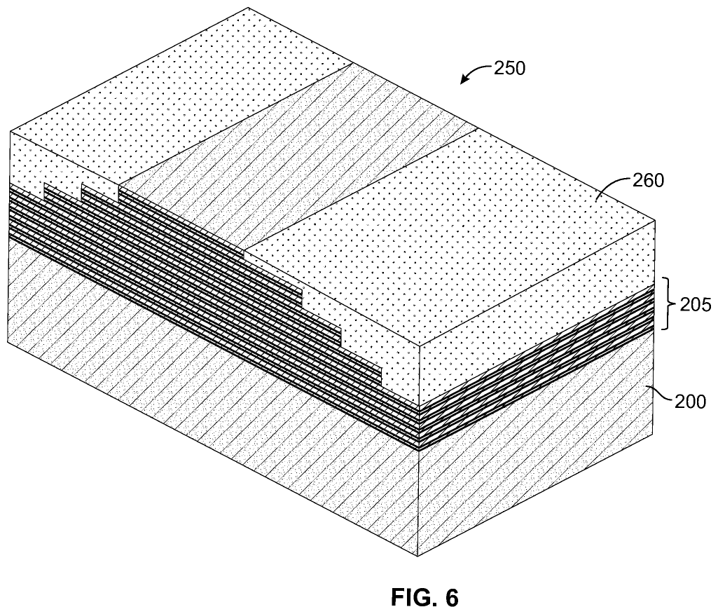

FIG. 6 illustrates the electronic device after deposition of a dielectric material 260 on the exposed surfaces of the staircase. As used herein, the term “dielectric material” refers to an electrical insulator that can be polarized in an electric field. The dielectric material 260 can be any suitable material known to the skilled artisan including, but not limited to, oxides, carbon doped oxides, silicon dioxide (SiO), porous silicon dioxide (SiO₂), silicon dioxide (SiO), silicon nitride (SiN), silicon dioxide/silicon nitride, carbides, oxycarbides, nitrides, oxynitrides, oxycarbonitrides, polymers, phosphosilicate glass, fluorosilicate (SiOF) glass, or organosilicate glass (SiOCH).

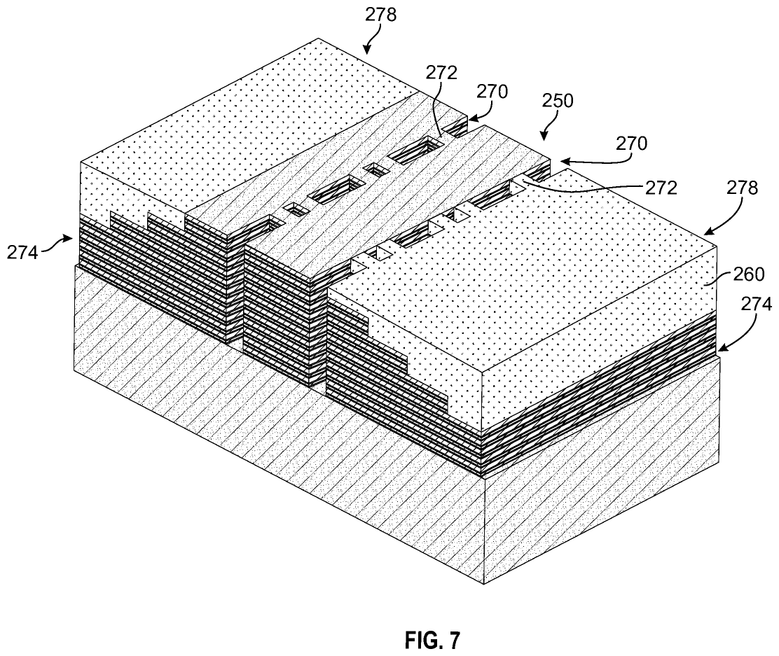

FIG. 7 illustrates the electronic device of FIG. 6 after isolating the memory region 250 by etching to leave isolation trenches 270 adjacent either side of the memory region 250. The isolation process can also form end trenches 274 which will bracket the wordlines that will be formed in a subsequent process. The isolation trenches 270 can be formed with bridges 272 that can provide electrical contact between the memory region 250 and the staircase region 278.

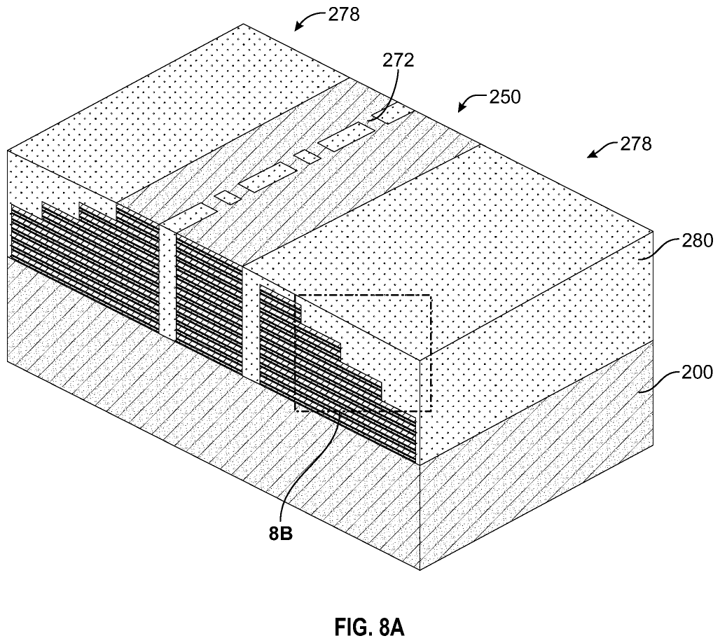

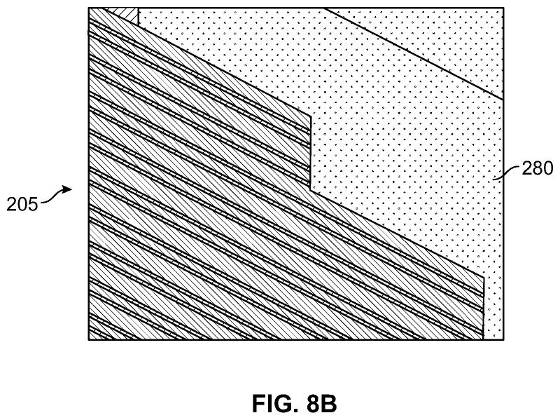

FIG. 8A illustrates the electronic device of FIG. 7 after deposition of additional dielectric material 280 to fill the isolation trenches 270 and end trenches 274. FIG. 8B shows an expanded view of region 8B shown in FIG. 8A. The dielectric material 280 of some embodiments comprises one or more of oxides, carbon doped oxides, silicon dioxide (SiO), porous silicon dioxide (SiO₂), silicon dioxide (SiO), silicon nitride (SiN), silicon dioxide/silicon nitride, carbides, oxycarbides, nitrides, oxynitrides, oxycarbonitrides, polymers, phosphosilicate glass, fluorosilicate (SiOF) glass, or organosilicate glass (SiOCH). The dielectric material 280 of some embodiments comprises the same material as dielectric material 260. In some embodiments, the additional dielectric material 280 is a different material than the dielectric material 260.

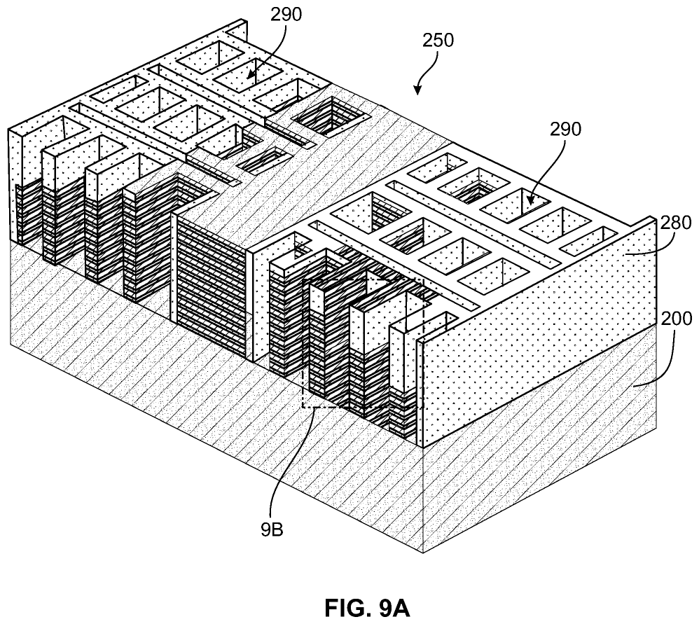

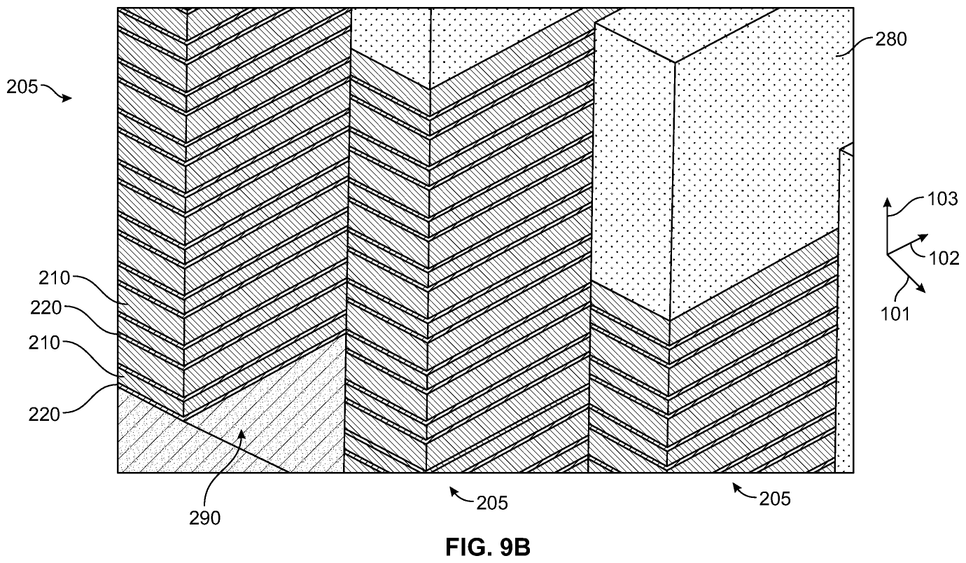

FIG. 9A illustrates the electronic device of FIG. 8A after a deep trench isolation process to leave wordline openings 290. FIG. 9B shows an expanded view of region 9B of FIG. 9A. The wordline openings 290 allows access to the layer stack 205 through the dielectric material 280. The wordline openings 290 can be formed by any suitable technique known to the skilled artisan. In some embodiments, the wordline openings 290 are formed by applying a hardmask over the substrate and performing a directional etch through the hardmask.

The deep trench isolation process leaves a plurality of layer stacks 205 spaced apart in a first direction 101 with each layer extending along a second direction 102 and the layers stacked in a third direction 103. The height of the layer stacks 205 decreases along the first direction 101 with the tallest stacks closest to the memory region 250, as in the staircase pattern shown above.

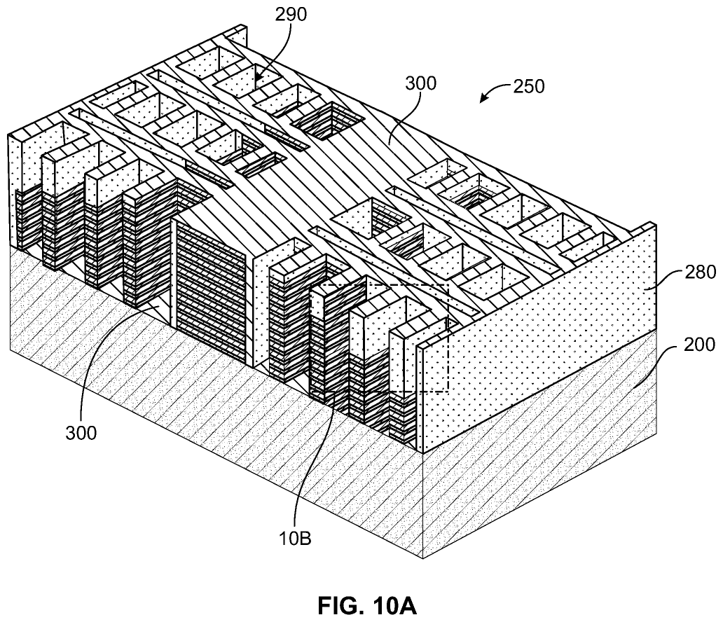

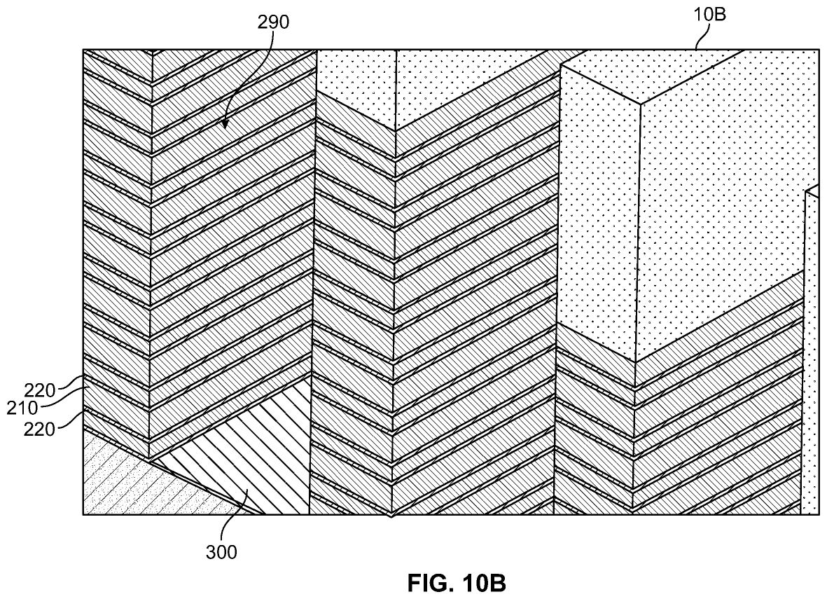

FIG. 10A illustrates the electronic device of FIG. 9A after deposition of an etch stop layer 300 on the top surface of the memory region 250 and the dielectric material 280. FIG. 10B shows an expanded view of region 10B of FIG. 10A. The etch stop layer 300 also forms on the top surface of the substrate 200 at the bottom of the wordline openings 290. The etch stop layer 300 can be formed by any suitable technique known to the skilled artisan. In some embodiments, the etch stop layer 300 is formed by a physical vapor deposition process that is directional to avoid or minimize deposition on the sidewalls of the wordline openings 290.

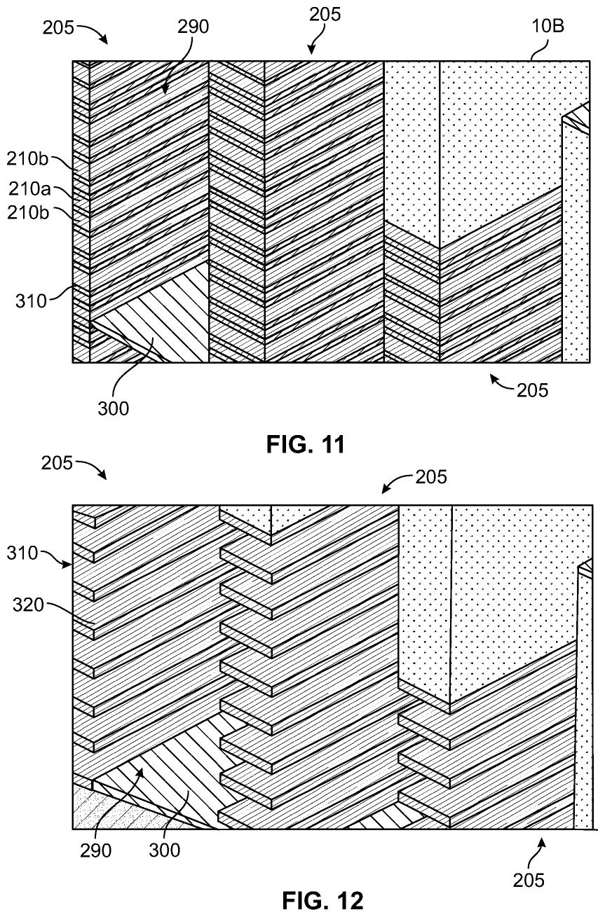

FIG. 11 shows region 10B of FIG. 10B after selectively recessing the second material layers 220 from a plurality of layer stacks 205 through the wordline openings 290 to form gaps 310. In some embodiments, the second material layers 220 comprises SiGe layers and the SiGe layers are selectively recessed through the wordline openings 290 to leave gaps 310 between adjacent first material layers 210. In some embodiments, the first material layers 210 comprises silicon and the layer stacks 205, after selectively recessing the second material layers 220, comprises alternating layers of thin layers 210a and thick layers 210b with gaps 310 between.

FIG. 12 shows the region of FIG. 11 after recessing the first material layers 210 through the wordline openings 290. Recessing (also referred to as etching) of the first material layers 210 through the wordline openings 290 can be done by any suitable technique known to the skilled artisan. Recessing the first material layers 210 removes the thin layers 210a and reduces the thickness of the thick layers 210b to leave a layer stack 205 with first material layers 320 spaced by gaps 310 in the third direction 103. In some embodiments, the first material layers 210 comprise silicon layers and recessing the silicon layers removes the thin silicon layers and reduces the thickness of the thick silicon layers to leave a layer stack with spaced silicon layers.

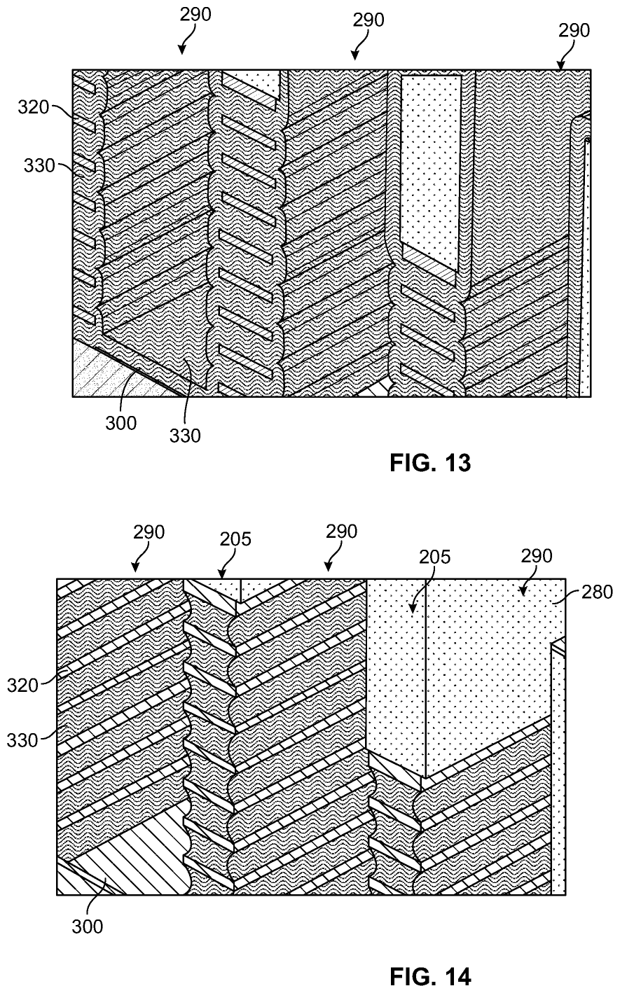

FIG. 13 shows the region of FIG. 12 after formation of a dielectric layer 330 between the spaced first material layers 320. The dielectric layer 330 is formed through the wordline openings 290 and leaves a film in the gaps 310 in the layer stack 205 and on the etch stop layer 300 on the bottom of the wordline openings 290. The dielectric layer 330 can be formed by any suitable technique known to the skilled artisan. In one or more embodiments, the dielectric layer 330 comprises one or more of oxides, carbon doped oxides, silicon dioxide (SiO), porous silicon dioxide (SiO₂), silicon dioxide (SiO), silicon nitride (SiN), silicon dioxide/silicon nitride, carbides, oxycarbides, nitrides, oxynitrides, oxycarbonitrides, polymers, phosphosilicate glass, fluorosilicate (SiOF) glass, or organosilicate glass (SiOCH). In some embodiments, the dielectric layer 330 is formed by atomic layer deposition. The dielectric layer 330 can be any suitable material known to the skilled artisan. In some embodiments, the dielectric layer 330 comprises an oxide. In some embodiments, the dielectric layer 330 comprises silicon oxide. In some embodiments, the dielectric layer 330 comprises a low-k dielectric material or a high-k dielectric material. In some embodiments, the first material layers 320 comprise silicon layers spaced in the third direction 103 and the dielectric layer 330 is formed between the spaced silicon layers.

FIG. 14 shows the region of FIG. 13 after removing the dielectric layer 330 from the sidewalls of the layer stacks 205. The dielectric layer 330 can be removed by any suitable technique known to the skilled artisan. In some embodiments, the dielectric layer 330 is removed from the sidewalls of the layer stack 205 using a non-directional etch process through the wordline openings 290.

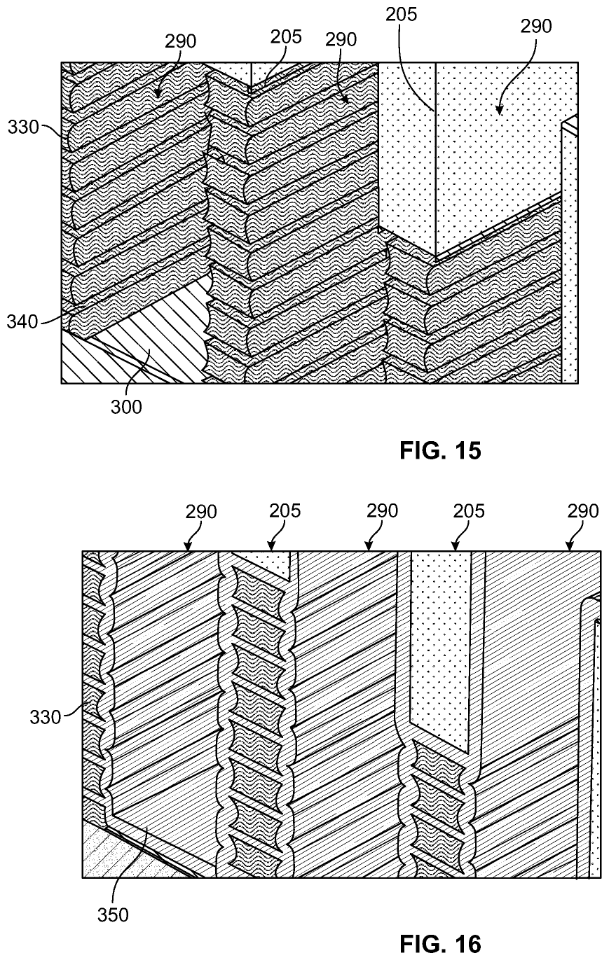

FIG. 15 shows the region of FIG. 14 after removing the spaced first material layers 320 from layer stacks 205 between the dielectric layer 330, leaving spaced dielectric layers 330. The spaced dielectric layers 330 alternate with gaps 340. In some embodiments, the first material layers 320 comprise silicon layers and the spaced silicon layers are removed from the layer stacks 205 through the wordline openings 290 to leave spaced dielectric layers 330.

FIG. 16 shows the region of FIG. 15 after depositing a metal layer 350 between the spaced dielectric layers 330. The metal layer 350 is formed in the gaps 340 between the spaced dielectric layers 330 through wordline openings 290 to form a layer stack 205 having alternating dielectric layers 330 and metal layers 350. The metal layer 350 can be formed by any suitable technique known to the skilled artisan. In some embodiments, the metal layer 350 is formed by atomic layer deposition. The metal layer 350 can be any suitable metal including, but not limited to, copper (Cu), cobalt (Co), tungsten (W), aluminum (Al), ruthenium (Ru), iridium (Ir), molybdenum (Mo), platinum (Pt), tantalum (Ta), titanium (Ti), or rhodium (Rh). In one or more embodiments, the wordline metal comprises tungsten (W). In other embodiments, the wordline metal comprises ruthenium (Ru). The metal layer 350 of some embodiments forms conformally on the exposed surfaces and inside the gaps in the layer stacks 205.

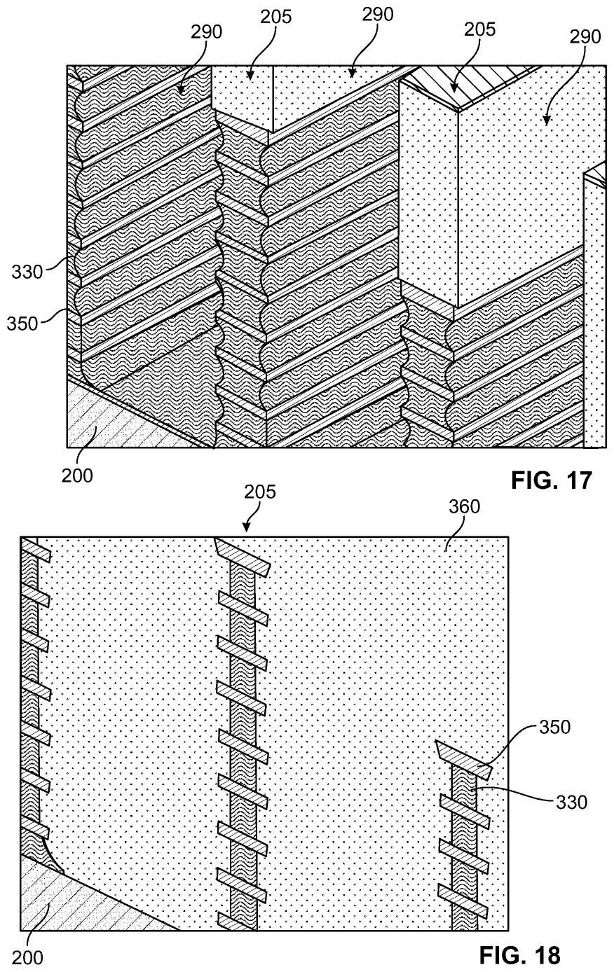

FIG. 17 shows the region of FIG. 16 after a sidewall metal recess process. The sidewall metal recess process removes the metal layer 350 from the surfaces and recesses the metal layer 350 between the spaced dielectric layers 330. The recessed metal layers 350 form the wordlines 120 that connect to the memory region 250. The wordlines extend outward from the memory region in a staircase pattern.

In some embodiments, the wordlines 120 further comprise formation of a barrier layer below the metal layer 350. The barrier layer may comprise any suitable material known to the skilled artisan. In one or more embodiments, the barrier layer comprises one or more of titanium nitride (TiN), tantalum nitride (TaN), or the like.

FIG. 18 shows the region of FIG. 17 after deposition of a gap fill material 360. The gap fill material 360 can be any suitable material that can electrically isolate the metal layers 350, which are the wordlines. The gap fill material 360 of some embodiments comprises the same material as the dielectric material 280. The gap fill material 360 can be deposited by any suitable technique known to the skilled artisan.

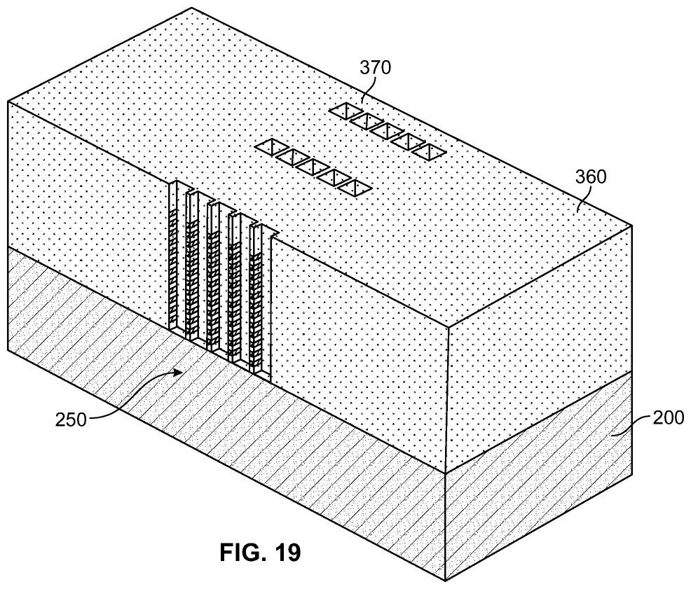

FIG. 19 shows the region of FIG. 18 after a bitline etch process to form vertical bitline openings 370. The vertical bitline openings 370 are located over the memory region 250 and extend along the third direction 103 to the substrate 200. The vertical bitline openings 370 can be formed by any suitable technique known to the skilled artisan.

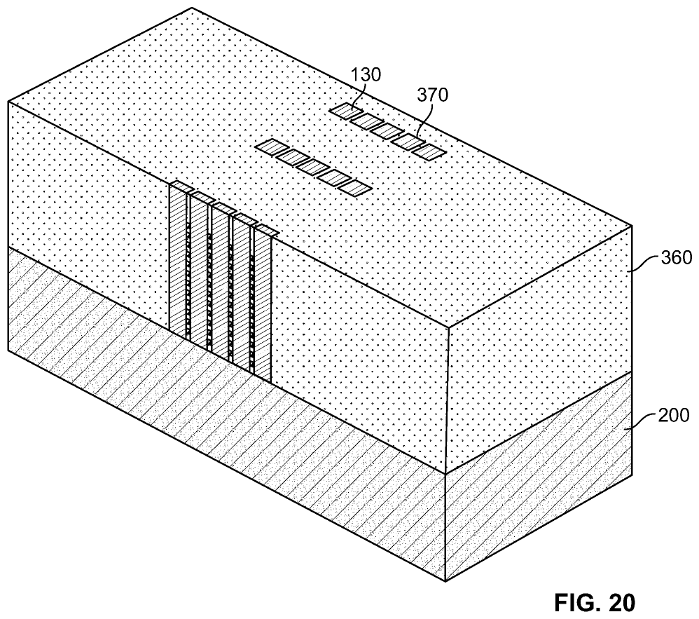

FIG. 20 shows the region of FIG. 19 after deposition of the vertical bitline 130 in the vertical bitline openings 370. The vertical bitlines 130 can be deposited by any suitable technique known to the skilled artisan and can be made of any suitable conductive material known to the skilled artisan. In some embodiments, the vertical bitlines 130 comprises one or more of titanium, titanium nitride, molybdenum or tungsten.

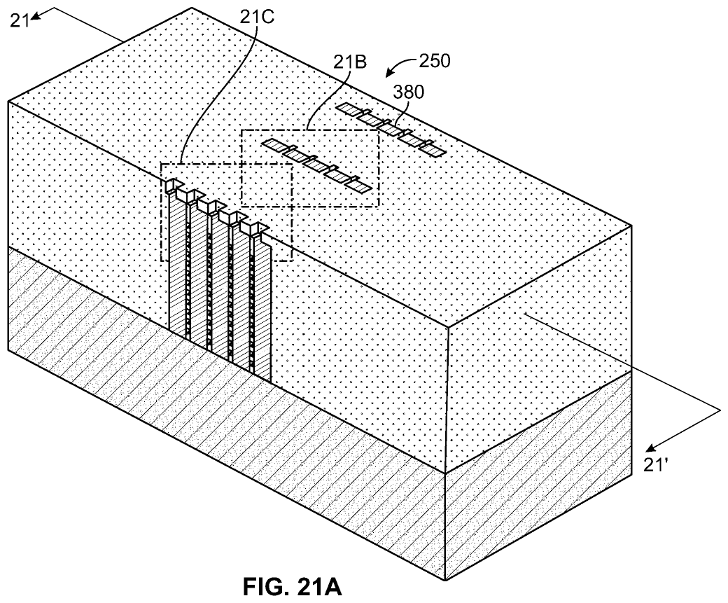

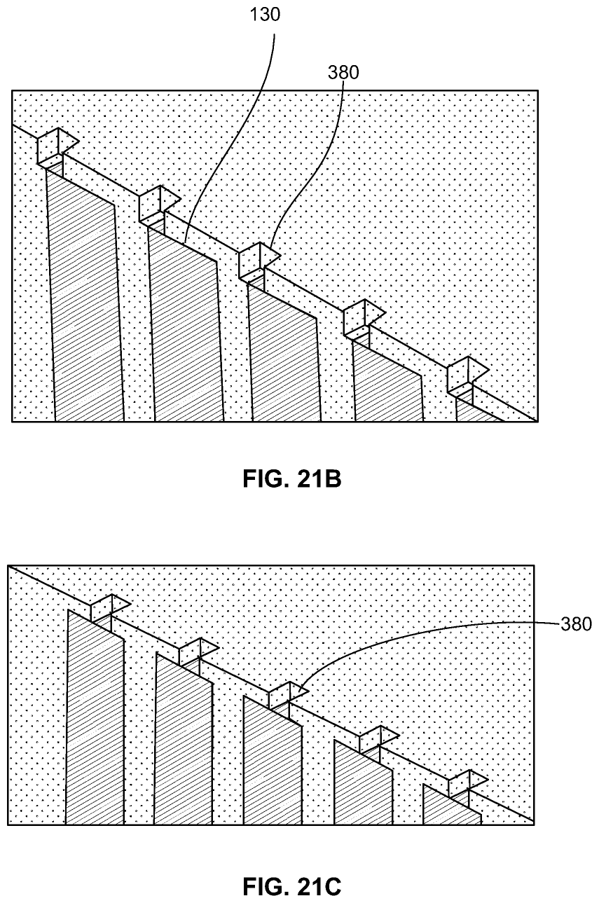

FIG. 21A shows the electronic device of FIG. 20 after etching bitline contact openings 380. FIG. 21B shows an expanded view of region 21C showing the bitline contact openings 380. FIG. 21C shows a cross-sectional view through the bitline contact openings 380 in region 21C along line 21-21′. The bitline contact openings 380 can be formed by any suitable technique known to the skilled artisan. In some embodiments, additional dielectric material 360 is first deposited on the surface of the vertical bitlines 130 formed in FIG. 20 followed by an etch process to open the bitline contact openings 380 over the vertical bitlines 130.

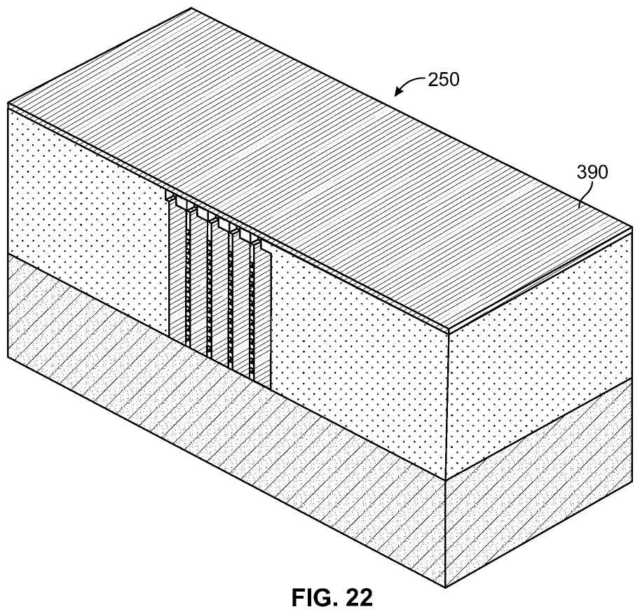

FIG. 22 shows the electronic device of FIG. 21A after depositing a bitline metal contact layer 390 on the surface of the substrate. The bitline metal contact layer 390 can be deposited by any suitable technique known to the skilled artisan and can include any suitable conductive material known to the skilled artisan. In some embodiments, the bitline metal contact layer 390 comprises the same material as the vertical bitlines 130. In some embodiments, the bitline metal contact layer 390 is formed by a blanket deposition process.

FIG. 23 shows the electronic device of FIG. 22 after formation of a bitline strap hardmask layer 400. The bitline strap hardmask layer 400 can be any suitable material that can be used as a hardmask for patterning purposes. In some embodiments, the bitline strap hardmask layer 400 is formed by a blanket deposition process.

FIG. 24A shows the electronic device of FIG. 23 after formation of the bitline strap, also referred to as a horizontal bitline 140. The bitline strap can be formed by any suitable technique known to the skilled artisan. In some embodiments, the bitline strap hardmask layer 400 is left on top of the horizontal bitlines 140 after etching the bitline straps. In some embodiments, the bitline strap hardmask layer 400 is removed from the horizontal bitlines 140 after formation of the horizontal bitlines 140. FIG. 24B shows an expanded view of region 24B of FIG. 24A to show the offset connections of the bitline straps with the vertical bitlines 130. FIG. 24C shows an expanded view of region 24C of FIG. 24A taken along line 24-24′.

In some embodiments, an optional bitline liner is formed below the bitline and can be made of any suitable material deposited by any suitable technique known to the skilled artisan. In some embodiments, the bitline liner is conformally deposited on an exposed surface of the dielectric. The bitline liner can be any suitable material including, but not limited to, titanium nitride (TiN) or tantalum nitride (TaN). In some embodiments, the optional bitline liner comprises or consists essentially of titanium nitride (TiN).

In some embodiments, the bitline metal comprises or consists essentially of one or more of tungsten silicide (WSi), tungsten nitride (WN), or tungsten (W). As used in this specification, the term “consists essentially of” means that the composition of the stated component is greater than or equal to 95%, 98%, 99% or 99.5% of the stated material. The bitline metal can be deposited by any suitable technique known to the skilled artisan and can be any suitable material. In one or more embodiments, forming the bitline metal further comprises forming a bitline metal seed layer (not shown) prior to depositing the bitline metal.

FIG. 25 shows the electronic device of FIG. 24 after a bitline strap capping deposition process. The bitline strap capping deposition process deposits dielectric material 380 over the bitline straps (horizontal bitlines 140) to electrically isolate the bitline straps. In some embodiments, the bitline strap capping comprises one or more of oxides, carbon doped oxides, silicon dioxide (SiO), porous silicon dioxide (SiO₂), silicon dioxide (SiO), silicon nitride (SiN), silicon dioxide/silicon nitride, carbides, oxycarbides, nitrides, oxynitrides, oxycarbonitrides, polymers, phosphosilicate glass, fluorosilicate (SiOF) glass, or organosilicate glass (SiOCH).

FIG. 26A shows the electronic device of FIG. 25 after formation of wordline contact openings 410. The front cross-sectional view illustrated in FIG. 26A is offset from the front cross-sectional view of FIG. 25 to pass through the wordline staircase rather than the spaced layer stacks 205. FIG. 26B is an expanded view of region 26B of FIG. 26A. The wordline contact openings 410 can be formed by any suitable technique known to the skilled artisan. The wordline contact openings 410 are formed in the third direction 103.

FIG. 27A shows the electronic device of FIG. 26A after formation of a wordline contact metal layer 420 on the substrate and in the wordline contact openings 410. FIG. 27B is an expanded view of region 27B of FIG. 27A. The wordline contact metal layer 420 can be any suitable conductive material deposited by any suitable technique. The conductive material deposited in the wordline contact openings 410 is the wordline contact 128 illustrated in FIGS. 1A and 2A.

FIG. 28 shows the electronic device of FIG. 27A after formation of a wordline contact strap hardmask 430 on the wordline contact metal layer 420. The wordline contact strap hardmask 430 can be formed by any suitable technique and of any suitable material known to the skilled artisan.

FIG. 29 shows the electronic device of FIG. 28 after etching the wordline contact straps 440 through the wordline contact strap hardmask 430 and wordline contact metal layer 420.

FIG. 30 shows the electronic device of FIG. 29 after a gap fill process to cover the wordline contact straps. The gap fill process of some embodiments uses the same dielectric material 280 as previously deposited. In some embodiments, a different dielectric material is used to fill the gaps between the wordline contact straps 440.

FIG. 31A shows the electronic device of FIG. 30 after etching vertical vias 450 along the third direction 103 to contact the horizontal bitlines 140. FIG. 31B shows an expanded view of region 31B of FIG. 31A. The vertical vias 450 can be formed by any suitable technique known to the skilled artisan.

FIG. 32 shows the electronic device of FIG. 31A after deposition of a via metal 460 and hardmask 470. The via metal 460 can be deposited by any suitable method known to the skilled artisan. The via metal 460 can by any suitable metal including, but not limited to, titanium, titanium nitride, tungsten or molybdenum. The hardmask 470 can be any suitable material deposited by any suitable method known to the skilled artisan.

FIG. 33A shows the electronic device of FIG. 32 after redistribution layer etching to form the redistribution layer 480. The redistribution layer 480 can be etched by any suitable technique known to the skilled artisan. FIG. 33B shows an expanded view of region 33B of FIG. 33A showing the redistribution layer 480 with via metal 460 contacting the bitline contact 145 extending in the third direction 103 and contacting the horizontal bitlines 140.

FIG. 34 shows the electronic device of FIG. 34 after deposition of an interlayer dielectric 490 on the redistribution layer 480. The interlayer dielectric 490 can be any suitable material known to the skilled artisan deposited by any suitable technique. In some embodiments, the interlayer dielectric 490 comprises the same material as one or more of the hardmask 470 or dielectric material 280. In some embodiments, the interlayer dielectric 490 comprises one or more of oxides, carbon doped oxides, silicon dioxide (SiO), porous silicon dioxide (SiO₂), silicon dioxide (SiO), silicon nitride (SiN), silicon dioxide/silicon nitride, carbides, oxycarbides, nitrides, oxynitrides, oxycarbonitrides, polymers, phosphosilicate glass, fluorosilicate (SiOF) glass, or organosilicate glass (SiOCH).

FIG. 35 shows the electronic device of FIG. 34 after etching vias 500 through the interlayer dielectric 490 to the via metal 460. The vias 500 can be formed by any suitable technique known to the skilled artisan. The interlayer dielectric 490 of some embodiments, as illustrated, is the same material as and is added to the dielectric material 280.

FIG. 36 shows the electronic device of FIG. 35 after deposition of via metal 510 in the vias 500. The via metal 510 can be deposited by any suitable technique known to the skilled artisan. The via metal 510 can be any suitable conductive material including, but not limited to, titanium, titanium nitride, tungsten or molybdenum. In some embodiments, the via metal 510 is deposited by a bulk deposition process followed by a suitable planarization process, for example, chemical-mechanical planarization (CMP).

FIG. 37 shows the electronic device of FIG. 36 after deposition of an interlayer dielectric 520 on the via metal 510. The interlayer dielectric 520 can be deposited by any suitable technique known to the skilled artisan. The interlayer dielectric 520 of some embodiments is a different material than the dielectric material 280. In some embodiments, the interlayer dielectric 520 comprises silicon carbonitride (SiCN). In some embodiments, the interlayer dielectric 520 comprises one or more of oxides, carbon doped oxides, silicon dioxide (SiO), porous silicon dioxide (SiO₂), silicon dioxide (SiO), silicon nitride (SiN), silicon dioxide/silicon nitride, carbides, oxycarbides, nitrides, oxynitrides, oxycarbonitrides, polymers, phosphosilicate glass, fluorosilicate (SiOF) glass, or organosilicate glass (SiOCH).

FIG. 38 shows the electronic device of FIG. 37 after deposition a bonding pad etch to create bonding pad openings 530. The bonding pad openings 530 are formed over the via metal 510. The bonding pad openings 530 can be formed by any suitable technique known to the skilled artisan.

FIG. 39 shows the electronic device of FIG. 38 after deposition of a barrier layer 540 on the interlayer dielectric 520 and in the bonding pad openings 530. The barrier layer 540 can be formed by any suitable process known to the skilled artisan. In some embodiments, the barrier layer 540 is formed by an atomic layer deposition process. The barrier layer 540 of some embodiments is a copper barrier layer. The barrier layer 540 of some embodiments is an optional layer and can be omitted.

FIG. 40 shows the electronic device of FIG. 39 after deposition of a seed layer 550 on the barrier layer 540. The seed layer 550 of some embodiments comprises a copper seed layer and the barrier layer 540 comprises a copper barrier layer. The seed layer 550 is an optional layer and can be omitted. The seed layer 550 can be formed by any suitable technique known to the skilled artisan. In some embodiments, the seed layer 550 is a conformal layer deposited using atomic layer deposition. In some embodiments, the seed layer 550 is deposited by a direction deposition process like physical vapor deposition to form on the top surface of the barrier layer 540 and/or on the bottom surface of the bonding pad openings 530.

FIG. 41 shows the electronic device of FIG. 40 after a metal plating process to form a metal layer 560. The metal layer 560 of some embodiments is deposited on the seed layer 550 and is made of the same material as the seed layer 550. In some embodiments, the metal layer 560 is deposited directly on the barrier layer 540. In some embodiments, the metal layer 560 is deposited directly on the interlayer dielectric 520 (which may be continuous with the dielectric material 280). The metal layer 560 can be deposited by any suitable technique known to the skilled artisan. In some embodiments, the metal layer 560 is deposited by a blanket deposition process (e.g., chemical vapor deposition or physical vapor deposition).

FIG. 42A shows the electronic device of FIG. 41 after formation of the bonding pads 570. The bonding pads 570 of some embodiments are formed by a planarization process (e.g., chemical-mechanical planarization (CMP)) to form a layer with regions of the metal layer 560 in bonding pad openings 530 in the interlayer dielectric 520. The bonding pads 570 connect to the vias that extend along the third direction 103 to contact either the wordline contact straps 440 or the horizontal bitlines 140. FIG. 42B shows region 42B of FIG. 42A showing the connection along the third direction 103 between the bonding pad 570 and the wordlines 120. FIG. 42C shows region 42C of FIG. 42A showing the connection along the third direction 103 between the bonding pad 570 and the horizontal bitlines 140.

FIG. 43 shows a portion of an electronic device formed by one or more of the embodiments described showing the conductive pathways to the staircase structure and the memory region 250. Each of the bonding pads 570 connect to one of the wordlines 120 or horizontal bitlines 140 through the various vias.

Additional embodiments of the disclosure are directed to processing tools 900 for the formation of the memory devices and methods described, as shown in FIG. 44. The cluster tool 900 includes at least one central transfer chamber 921, 931 with a plurality of sides. A robot 925, 935 is positioned within the central transfer chamber 921, 931 and is configured to move a robot blade and a wafer to each of the plurality of sides.

The cluster tool 900 comprises a plurality of processing chambers 902, 904, 906, 908, 910, 912, 914, 916, and 918, also referred to as process stations, connected to the central transfer station. The various processing chambers provide separate processing regions isolated from adjacent process stations. The processing chamber can be any suitable chamber including, but not limited to, a preclean chamber, a buffer chamber, transfer space(s), a wafer orienter/degas chamber, a cryo cooling chamber, a deposition chamber, annealing chamber, etching chamber, a selective etching chamber, and the like. The particular arrangement of process chambers and components can be varied depending on the cluster tool and should not be taken as limiting the scope of the disclosure.

In the embodiment shown in FIG. 44, a factory interface 950 is connected to a front of the cluster tool 900. The factory interface 950 includes a loading chamber 954 and an unloading chamber 956 on a front 951 of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the cluster tool 900. In the embodiment shown, the loading chamber 954 and unloading chamber 956 are sized to hold a wafer cassette with a plurality of wafers positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock chamber 962 and the unloading chamber 956.

The cluster tool 900 shown has a first section 920 and a second section 930. The first section 920 is connected to the factory interface 950 through load lock chambers 960, 962. The first section 920 includes a first transfer chamber 921 with at least one robot 925 positioned therein. The robot 925 is also referred to as a robotic wafer transport mechanism. The first transfer chamber 921 is centrally located with respect to the load lock chambers 960, 962, process chambers 902, 904, 916, 918, and buffer chambers 922, 924. The robot 925 of some embodiments is a multi-arm robot capable of independently moving more than one wafer at a time. In some embodiments, the first transfer chamber 921 comprises more than one robotic wafer transfer mechanism. The robot 925 in first transfer chamber 921 is configured to move wafers between the chambers around the first transfer chamber 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo cool the wafer before processing in the second section 930 or allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit (CPU), memory, suitable circuits, and storage.

Processes may generally be stored in the memory of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below”, or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A memory device comprising:
a plurality of memory cell units, each memory cell unit comprising a plurality of memory cells arranged in at least two layers, each layer having memory cells arranged in a grid pattern along with a number of first memory cells spaced in a first direction, a number of second memory cells spaced in a second direction, the at least two layers spaced in a third direction, each memory cell comprising a capacitor and a transistor;
each of the at least two layers comprises a wordline extending from the grid pattern along the first direction, each of the wordlines in electrical connection with each memory cell in the layer, the wordlines forming a staircase pattern with a surface accessible along the third direction;
a plurality of vertical bitlines for each of the first memory cells, the vertical bitlines located between each of the memory cell units; and
a plurality of horizontal bitlines above the plurality of memory cell units and extending along the second direction, each of the plurality of horizontal bitlines in electrical connection with one of the plurality of vertical bitlines adjacent the memory cell unit.

2. The memory device of claim 1, wherein each memory cell unit has at least twice the number of horizontal bitlines than wordlines.

3. The memory device of claim 1, further comprising a wordline contact extending in the third direction from the surface accessible along the third direction.

4. The memory device of claim 1, further comprising a bitline contact extending in the third direction from each of the horizontal bitlines.

5. The memory device of claim 1, wherein each of the memory cell units independently comprise a stack of alternating insulator layers and metal layers.

6. The memory device of claim 5, wherein the insulator layer comprises an oxide layer.

7. The memory device of claim 6, wherein the oxide layer comprises silicon oxide.

8. A method of forming a memory device, the method comprising:
forming a plurality of memory cell units, each unit comprising a plurality of memory cells arranged in at least two layers, each layer having a grid pattern, each layer having a wordline extending from the plurality of memory cells in a first direction, each memory cell unit having a vertical bitline extending along a third direction and located adjacent the memory cell unit along a second direction, and horizontal bitlines over the memory cell units, the horizontal bitlines in electrical connection with one vertical bitline on a side of the memory cell unit.

9. The method of claim 8, wherein each of the memory cells in a layer are connected to the same wordline.

10. The method of claim 9, wherein the wordlines form a staircase pattern with a surface accessible along the third direction.

11. The method of claim 10, further comprising forming a wordline contact extending in the third direction from the surface accessible along the third direction.

12. The method of claim 8, further comprising forming bitline contacts extending in the third direction from a surface of the horizontal bitlines.

13. A method of forming a memory device, the method comprising:
selectively recessing SiGe layers of a plurality of layer stacks through wordline openings formed adjacent a memory region, the layer stacks comprising alternating layers of SiGe and silicon, the silicon layers alternating between a thin layer and a thick layer, the plurality of layer stacks spaced apart in a first direction with each layer extending along a second direction and the layers stacked in a third direction, a height of the layer stacks decreasing along the first direction with a tallest stack closest to the memory region;
recessing the silicon layers to remove the thin layers and reduce a thickness of the thick layers to leave a layer stack with spaced silicon layers;
forming a dielectric layer between the spaced silicon layers;
removing the spaced silicon layers from the layer stack to leave spaced dielectric layers; and
forming wordlines by depositing a metal layer between the spaced dielectric layers to form a layer stack having alternating dielectric layers and wordlines comprising metal layers, the wordlines extending outward from the memory region in a staircase pattern.

14. The method of claim 13, further comprising forming wordline contacts along the third direction to contact the wordlines.

15. The method of claim 13, further comprising forming horizontal bitlines above the memory region, the horizontal bitlines contacting vertical bitlines within the memory region.
